(19) United States
(12) Patent Application Publication
(10) Pub. No.: US 2026/0182133 A1
(43) Pub. Date: Jun. 25, 2026

(54) LIGHT EMITTING DEVICE, LIGHT EMITTING SUBSTRATE, BACKLIGHT MODULE AND DISPLAY APPARATUS

(71) Applicants: BOE MLED TECHNOLOGY CO., LTD., Beijing (CN); BOE TECHNOLOGY GROUP CO., LTD., Beijing (CN)

(72) Inventors: Shanwei YANG, Beijing (CN); Lili JIA, Beijing (CN); Yutao HAO, Beijing (CN); Junjie MA, Beijing (CN); Yuanda LU, Beijing (CN); Xinxin ZHAO, Beijing (CN); Xueqiao LI, Beijing (CN)

(73) Assignees: BOE MLED TECHNOLOGY CO., LTD., Beijing (CN); BOE TECHNOLOGY GROUP CO., LTD., Beijing (CN)

(21) Appl. No.: 18/840,177

(22) PCT Filed: Mar. 31, 2023
(86) PCT No.: PCT/CN2023/085715

§ 371 Date: Aug. 21, 2024

(51) Int. Cl. H10H 29/80; H10H 20/831; H10H 29/24; H10H 29/85

(52) U.S. Cl. CPC H10H 29/942; H10H 20/831; H10H 29/24; H10H 29/857

(57) ABSTRACT

A light emitting device, a light emitting substrate, a backlight module and a display apparatus are provided. The light emitting device includes: a base substrate; a plurality of light emitting units, located on the base substrate and connected in series; a first electrode, connected with one end of the plurality of light emitting units connected in series; a second electrode, connected with the other end of the plurality of light emitting units connected in series; and a bridge electrode, connecting two light emitting units among the plurality of light emitting units; an orthographic projection of at least one of the first electrode and the second electrode on the base substrate overlaps with orthographic projections of at least two light emitting units among the plurality of light emitting units on the base substrate.

### TECHNICAL FIELD

Embodiments of the present disclosure relate to a light emitting device, a light emitting substrate, a backlight module and a display apparatus.

### BACKGROUND

As compared with the traditional liquid crystal display (LCD) products, a light emitting diode (LED) device with a dimension between 100 μm to 300 μm is referred to as a sub-millimeter light emitting diode (a Mini LED), and a micro light emitting diode (a Micro LED) has a dimension below 100 μm.

A Micro LED or Mini LED backlight may implement precise brightness partition adjustment, may effectively meet the needs of high partition count, and may well implement functions of high dynamic range (HDR), which has characteristics such as high precision partition, high dynamic contrast, high color gamut, and high brightness, and may implement more realistic display effects. The product series cover a full range of products such as commercial displays, televisions (TV), monitors (MNT), notebooks (NB), vehicle-mounted displays, and virtual reality (VR) displays.

### SUMMARY

Embodiments of the present disclosure provide a light emitting device, a light emitting substrate, a backlight module and a display apparatus.

Embodiments of the present disclosure provide a light emitting device, which includes: a base substrate; a plurality of light emitting units, located on the base substrate and connected in series; a first electrode, connected with one end of the plurality of light emitting units connected in series; a second electrode, connected with the other end of the plurality of light emitting units connected in series; and a bridge electrode, connecting two light emitting units among the plurality of light emitting units; an orthographic projection of at least one of the first electrode and the second electrode on the base substrate overlaps with orthographic projections of at least two light emitting units among the plurality of light emitting units on the base substrate.

In the light emitting device provided by embodiments of the present disclosure, the first electrode and the second electrode are spaced apart from each other, the first electrode and the second electrode are arranged in a first direction, each of the first electrode and the second electrode extends in a second direction, and the first direction intersects with the second direction.

In the light emitting device provided by embodiments of the present disclosure, a ratio of a maximum dimension of the base substrate in the first direction to a maximum dimension of the base substrate in the second direction is (1 to 1.18): 1.

In the light emitting device provided by embodiments of the present disclosure, a ratio of a maximum dimension of the plurality of light emitting units in the first direction to a maximum dimension of the plurality of light emitting units in the second direction is (1 to 1.18): 1.

In the light emitting device provided by embodiments of the present disclosure, a ratio of a maximum dimension of each of the first electrode and the second electrode in the first direction to a maximum dimension of the plurality of light emitting units in the first direction is greater than 19%.

In the light emitting device provided by embodiments of the present disclosure, the ratio of the maximum dimension of each of the first electrode and the second electrode in the first direction to the maximum dimension of the plurality of light emitting units in the first direction is less than or equal to 26%.

In the light emitting device provided by embodiments of the present disclosure, a gap is provided between the first electrode and the second electrode, and a ratio of a minimum dimension of the gap in the first direction to a maximum dimension of the plurality of light emitting units in the first direction is greater than or equal to 30% and less than or equal to 35%.

In the light emitting device provided by embodiments of the present disclosure, the plurality of light emitting units include a first light emitting unit, a second light emitting unit, a third light emitting unit, and a fourth light emitting unit, and the bridge electrode includes a first bridge electrode, a second bridge electrode, and a third bridge electrode.

In the light emitting device provided by embodiments of the present disclosure, the first light emitting unit and the second light emitting unit are connected through the first bridge electrode, the second light emitting unit and the third light emitting unit are connected through the second bridge electrode, and the third light emitting unit and the fourth light emitting unit are connected through the third bridge electrode.

In the light emitting device provided by embodiments of the present disclosure, the first light emitting unit, the second light emitting unit, the third light emitting unit, and the fourth light emitting unit are respectively located within four regions partitioned by two midlines of the base substrate, the first light emitting unit and the second light emitting unit are arranged in the second direction, the third light emitting unit and the fourth light emitting unit are arranged in the second direction, the first light emitting unit and the fourth light emitting unit are arranged in the first direction, and the second light emitting unit and the third light emitting unit are arranged in the first direction.

In the light emitting device provided by embodiments of the present disclosure, at least a portion of the first bridge electrode and at least a portion of the third bridge electrode are located between the first electrode and the second electrode, the second bridge electrode extends in the first direction, and is located on a side where short edges of the first electrode and the second electrode are located.

In the light emitting device provided by embodiments of the present disclosure, each of the first bridge electrode and the third bridge electrode extends in the second direction, and an orthographic projection of each of the first bridge electrode and the third bridge electrode on the base substrate does not overlap with orthographic projections of the first electrode and the second electrode on the base substrate.

In the light emitting device provided by embodiments of the present disclosure, each of the first bridge electrode and the third bridge electrode includes a first portion extending in the first direction and a second portion extending in the second direction, orthographic projections of the first portion of the first bridge electrode and the first portion of the third bridge electrode on the base substrate respectively overlap with the orthographic projections of the first electrode and the second electrode on the base substrate, an orthographic projection of the second portion of the first bridge electrode on the base substrate does not overlap with the orthographic projection of the first electrode on the base substrate, and an orthographic projection of the second portion of the third bridge electrode does not overlap with the orthographic projection of the second electrode on the base substrate.

In the light emitting device provided by embodiments of the present disclosure, the bridge electrode further includes a fourth bridge electrode and a fifth bridge electrode, the first light emitting unit and the second light emitting unit are also connected through the fourth bridge electrode, the third light emitting unit and the fourth light emitting unit are also connected through the fifth bridge electrode, the fourth bridge electrode and the first bridge electrode are located on both sides of the first electrode, and the fifth bridge electrode and the second bridge electrode are located on both sides of the second electrode.

In the light emitting device provided by embodiments of the present disclosure, the first bridge electrode is Z-shaped, the second bridge electrode is L-shaped, and the third bridge electrode is L-shaped.

In the light emitting device provided by embodiments of the present disclosure, the first light emitting unit, the second light emitting unit, the third light emitting unit, and the fourth light emitting unit are respectively located in four regions partitioned by the two midlines of the base substrate, the first light emitting unit and the second light emitting unit are arranged in the second direction, the third light emitting unit and the fourth light emitting unit are arranged in the second direction, the first light emitting unit and the third light emitting unit are arranged in the first direction, and the second light emitting unit and the fourth light emitting unit are arranged in the first direction, the second bridge electrode includes an inclined portion, and the inclined portion is inclined relative to the first direction and inclined relative to the second direction.

In the light emitting device provided by embodiments of the present disclosure, the third bridge electrode has a middle portion extending in the first direction and portions located on both sides of the middle portion and both extending in the second direction.

In the light emitting device provided by embodiments of the present disclosure, the bridge electrode further includes a first connection electrode and a second connection electrode, an orthographic projection of the first connection electrode on the base substrate is located within an orthographic projection of the first light emitting unit on the base substrate, and an orthographic projection of the second connection electrode on the base substrate is located within an orthographic projection of the fourth light emitting unit on the base substrate.

In the light emitting device provided by embodiments of the present disclosure, the second bridge electrode has an opening, and the opening of the second bridge electrode faces the first light emitting unit.

In the light emitting device provided by embodiments of the present disclosure, the first light emitting unit, the second light emitting unit, the third light emitting unit, and the fourth light emitting unit are respectively located in four regions partitioned by two diagonals of a rectangle, the first light emitting unit and the fourth light emitting unit are arranged in the first direction, the second light emitting unit and the third light emitting unit are arranged in the second direction, and the second bridge electrode passes through an intersection of the two diagonals.

In the light emitting device provided by embodiments of the present disclosure, at least one selected from the group consisting of the first bridge electrode, the second bridge electrode, and the third bridge electrode has a bent portion.

In the light emitting device provided by embodiments of the present disclosure, the first light emitting unit, the second light emitting unit, the third light emitting unit, and the fourth light emitting unit are arranged in the second direction, the first bridge electrode and the second bridge electrode are respectively arranged on both sides of the second light emitting unit in the first direction, and the second bridge electrode and the third bridge electrode are respectively arranged on both sides of the third light emitting unit in the first direction.

In the light emitting device provided by embodiments of the present disclosure, at least one selected from the group consisting of the first bridge electrode, the second bridge electrode, and the third bridge electrode is Z-shaped.

In the light emitting device provided by embodiments of the present disclosure, a thickness of each of the first electrode E1 and the second electrode E2 is greater than or equal to 8 μm.

In the light emitting device provided by embodiments of the present disclosure, the thickness of each of the first electrode and the second electrode is less than or equal to 15 μm.

In the light emitting device provided by embodiments of the present disclosure, each of the first electrode and the second electrode includes a first electrode portion and a second electrode portion that are stacked.

In the light emitting device provided by embodiments of the present disclosure, a material of the second electrode portion includes solder, and the first electrode portion and the second electrode portion are made of different materials.

In the light emitting device provided by embodiments of the present disclosure, the light emitting device further includes a damage preventing structure, the damage preventing structure is located within a region surrounded by the first light emitting unit, the second light emitting unit, the third light emitting unit, and the fourth light emitting unit, and no conductive structure is provided within a region where the damage preventing structure is located.

In the light emitting device provided by embodiments of the present disclosure, the light emitting device further includes a first passivation layer, a second passivation layer, and a third passivation layer, the bridge electrode is located on the first passivation layer, the second passivation layer is located on the bridge electrode, the third passivation layer is located on the second passivation layer, and the third passivation layer also serves as a distributed Bragg reflector.

In the light emitting device provided by embodiments of the present disclosure, the light emitting device further includes a distributed Bragg reflector film layer, the distributed Bragg reflector film layer is located on a side of the base substrate that is not provided with the plurality of light emitting units.

Embodiments of the present disclosure further provide a light emitting substrate, including any one of the light emitting devices as mentioned above.

Embodiments of the present disclosure further provide a backlight module, including any one of the light emitting substrates as mentioned above.

Embodiments of the present disclosure further provide a display apparatus, including any one of the backlight modules as mentioned above.

### BRIEF DESCRIPTION OF DRAWINGS

In order to more clearly illustrate the technical solutions of the embodiments of the present disclosure, the drawings of the embodiments will be briefly described in the following, it is obvious that the described drawings below are only related to some embodiments of the present disclosure and thus are not limitative to the present disclosure.

FIG. 1 is a cross-sectional view of a base plate and a manufacturing process diagram of the base plate.

FIG. 2 is a cross-sectional view of a base plate and a manufacturing process diagram of the base plate.

FIG. 3 is a schematic diagram of rotation during die bonding.

FIG. 4 shows a schematic diagram of a light emitting device.

FIG. 5 is a schematic diagram of region partition of a light emitting device provided by an embodiment of the present disclosure.

FIG. 6 is a schematic diagram of a light emitting unit, a first electrode and a second electrode in a light emitting device provided by an embodiment of the present disclosure.

FIG. 7 is a schematic diagram of a light emitting device provided by an embodiment of the present disclosure.

FIG. 8 is a schematic diagram of dimensioning of a light emitting device provided by an embodiment of the present disclosure.

FIG. 9 is a layout diagram of a light emitting device provided by an embodiment of the present disclosure.

FIG. 10 is a schematic diagram of a dimension of a light emitting device provided by an embodiment of the present disclosure.

FIG. 11 is a layout diagram of a light emitting device provided by an embodiment of the present disclosure.

FIG. 12 is a schematic diagram of a dimension of a light emitting device provided by an embodiment of the present disclosure.

FIG. 13 is a layout diagram of a light emitting device provided by an embodiment of the present disclosure.

FIG. 14 is a layout diagram of a light emitting device provided by an embodiment of the present disclosure.

FIG. 15 is a schematic diagram of a dimension of a light emitting device provided by an embodiment of the present disclosure.

FIG. 16 is a schematic diagram of region partition of a light emitting device and a light emitting unit in the light emitting device provided by an embodiment of the present disclosure.

FIG. 17 is a layout diagram of a light emitting device provided by an embodiment of the present disclosure.

FIG. 18 is a schematic diagram of a light emitting device provided by an embodiment of the present disclosure.

FIG. 19 is a schematic diagram of a light emitting device provided by an embodiment of the present disclosure.

FIG. 20 is a schematic diagram of region partition of a light emitting device provided by an embodiment of the present disclosure.

FIG. 21 is a schematic diagram of a light emitting unit, a first electrode and a second electrode in a light emitting device provided by an embodiment of the present disclosure.

FIG. 22 is a schematic diagram of dimensioning of a light emitting device provided by an embodiment of the present disclosure.

FIG. 23 is a layout diagram of a light emitting device provided by an embodiment of the present disclosure.

FIG. 24 is a schematic diagram of a dimension of a light emitting device provided by an embodiment of the present disclosure.

FIG. 25 is a schematic diagram of a light emitting device provided by an embodiment of the present disclosure.

FIG. 26 is a schematic diagram of a light emitting device provided by an embodiment of the present disclosure.

FIG. 27 is a schematic diagram of region partition of a light emitting device provided by an embodiment of the present disclosure.

FIG. 28 is a schematic diagram of a light emitting unit, a first electrode and a second electrode in a light emitting device provided by an embodiment of the present disclosure.

FIG. 29 is a schematic diagram of a light emitting device provided by an embodiment of the present disclosure.

FIG. 30 is a layout diagram of a light emitting device provided by an embodiment of the present disclosure.

FIG. 31 is a schematic diagram of a dimension of a light emitting device provided by an embodiment of the present disclosure.

FIG. 32 is a schematic diagram of a structure and a dimension of a light emitting device provided by another embodiment of the present disclosure.

FIG. 33 is a schematic diagram of a light emitting device provided by an embodiment of the present disclosure.

FIG. 34 is a schematic diagram of a light emitting device provided by an embodiment of the present disclosure.

FIG. 35 is a cross-sectional view of a light emitting device provided by an embodiment of the present disclosure.

FIG. 36 is a cross-sectional view of a light emitting device provided by another embodiment of the present disclosure.

FIG. 37 is a cross-sectional view of a light emitting device provided by another embodiment of the present disclosure.

FIG. 38 is a schematic diagram of a light emitting substrate provided by an embodiment of the present disclosure.

FIG. 39 is a schematic diagram of a display apparatus provided by an embodiment of the present disclosure.

### DETAILED DESCRIPTION

In order to make objectives, technical details and advantages of the embodiments of the present disclosure more clearly, the technical solutions of the embodiments will be described in a clearly and fully understandable way in connection with the drawings related to the embodiments of the present disclosure. Apparently, the described embodiments are just a part but not all of the embodiments of the present disclosure. Based on the described embodiments herein, those skilled in the art can obtain other embodiment(s), without any inventive work, which should be within the scope of the present disclosure.

Unless otherwise defined, all the technical and scientific terms used herein have the same meanings as commonly understood by one of ordinary skill in the art to which the present disclosure belongs. The terms “first,” “second,” etc., which are used in the present disclosure, are not intended to indicate any sequence, amount or importance, but distinguish various components. Also, the terms “comprise,” “comprising,” “include,” “including,” etc., are intended to specify that the elements or the objects stated before these terms encompass the elements or the objects and equivalents thereof listed after these terms, but do not preclude the other elements or objects. The phrases “connect”, “connected”, etc., are not intended to define a physical connection or mechanical connection, but may include an electrical connection, directly or indirectly.

At present, in the field of Mini LED backlight, the main focus of research and development by respective manufacturers is substantially a solution of a backlight based on a printed circuit board (PCB) substrate carrying passive matrix (PM) driven Mini LEDs. However, the traditional backlight based on PCB substrate has disadvantages of high power consumption and poor heat dissipation, so Mini LED backlight HDR 1400 based on PCB substrate requires fan cooling. Meanwhile, due to a large warping degree of PCB, a lamp board needs splicing, and the large warping degree in turn makes the PCB splicing seams larger, which is very prone to problems such as uneven brightness (Mura) of splicing seams. A glass substrate has advantages such as high reflectivity, good heat dissipation, thin thickness, good warping control, and high line precision, making it highly competitive in the field of Mini LED backlight.

Based on extensive experience in developing glass base plates, BOE has taken the lead in proposing a solution of a backlight based on glass substrate carrying active matrix (AM) driven Mini LEDs, which has high flatness, good heat dissipation performance, and is matched with high-precision wiring and high-speed die bonding technology. The backlight with light emitting devices (chips) directly bonded to glass, chip on glass (COG-substrate)+AM driven Mini LEDs, has high flatness in the entire plane and better temperature and humidity resistance of the substrate, which not only has a stylish design with ultra-thin integration and no horizontal splicing seams, but also can easily reach up to 10,000 partitions; can implement ultra-high brightness of 4,000 nit, while presenting fine partition of 5K to 10K; and can optimize quality of display images and ensure healthy display without flicker, in combination with a solution of AM driven low-frequency flashing.

To achieve an object of low power consumption, the usual glass-substrate Mini LED backlight mostly adopts a Mini LED with high-voltage of 6V and with dimensions such as 0620, 0818, 0916, etc. However, in order to reach high brightness, the Mini LED with high-voltage of 6V has to use a larger current to meet the brightness design requirements, so design of thicker trace on the COG-substrate is needed to meet driving requirements. The light emitting device with a dimension of 0620 refers to a Mini LED with a dimension of 06 mil*20 mil. The light emitting device with a dimension of 0818 refers to a Mini LED with a dimension of 08 mil*18 mil. The light emitting device with a dimension of 0916 refers to a Mini LED with a dimension of 09 mil*16 mil. Mil is an imperial unit and a length unit; and 1 mil is equal to 0.0254 mm.

For example, with respect to a TV project, under a peak brightness requirement of 1,500 nit in a module (MDL), an operating current of a Mini LED with high-voltage of 6V is 13.6 mA, which requires design of copper trace with a thickness of 4.5 μm (copper thickness, i.e., Cu thickness). If a high-voltage 12V Mini LED is used, an operating current may be reduced to 6.96 mA, only requiring a copper trace with a thickness of 2.6 μm. With respect to an MNT project, under a peak brightness requirement of 1,600 nit in a MDL, an operating current of a Mini LED with high-voltage of 6V is 3.8 mA, which requires Cu thickness design of 2.8 μm. If a high-voltage 12V Mini LED is used, an operating current may be reduced to 1.85 mA, and a Cu thickness on the base plate (BP) may be reduced to 1.6 μm.

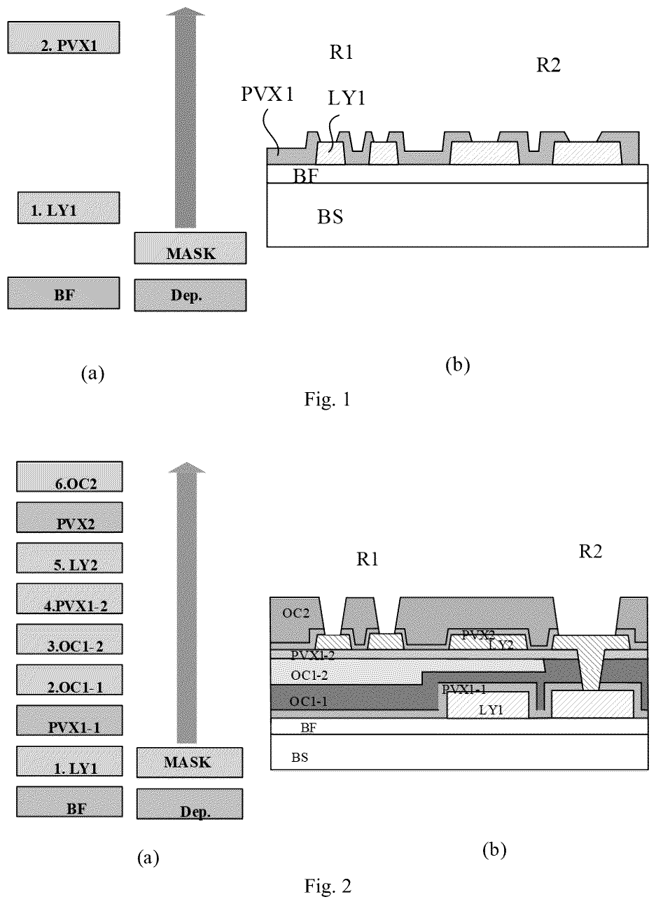

FIG. 1 is a cross-sectional view of a base plate and a manufacturing process diagram of the base plate. FIG. 2 is a cross-sectional view of a base plate and a manufacturing process diagram of the base plate.

In FIG. 1 and FIG. 2, “Dep.” represents a deposition process, and “MASK” represents a mask process.

FIG. 1 shows a conductive pattern layer LY1 and a passivation layer PVX1. The base plate shown in FIG. 1 requires two mask processes. That is, a first mask process is used for forming the conductive pattern layer LY1; and a second mask process is used for forming the passivation layer PVX1.

FIG. 2 also shows the conductive pattern layer LY1, a passivation layer PVX1-1, an optical adhesive layer OC1-1, an optical adhesive layer OC1-2, a passivation layer PVX1-2, a conductive pattern layer LY2, a passivation layer PVX2, and an optical adhesive layer OC2. The base plate shown in FIG. 2 requires six mask processes. That is, a first mask process is used for forming the conductive pattern layer LY1, a second mask process is used for forming the passivation layer PVX1-1 and the optical adhesive layer OC1-1, a third mask process is used for forming the optical adhesive layer OC1-2, a fourth mask process is used for forming the passivation layer PVX1-2, a fifth mask process is used for forming the conductive pattern layer LY2, and a sixth mask process is used for forming the passivation layer PVX2 and the optical adhesive layer OC2. Usually, one mask plate is used for each mask process.

FIG. 1 and FIG. 2 show a base substrate BS and a buffer layer BF located on the base substrate BS. FIG. 1 and FIG. 2 further show a bonding region R1 and a bonding region R2. For example, the bonding region R1 is an LED bonding region; and the bonding region R2 is a flexible printed circuit (FPC) bonding region.

The conductive pattern layer LY1 and the conductive pattern layer LY2 are respectively made of conductive materials. The conductive material of the conductive pattern layer LY1 includes a metal, for example, copper (Cu), also referred to as a copper (Cu) trace. The conductive material of the conductive pattern layer LY2 includes a metal, for example, copper (Cu), also referred to as a copper (Cu) trace. Of course, the copper (Cu) trace may also contain other elements. Usually, a Cu element makes up a relatively large proportion in a Cu trace.

The current base plate has Cu trace capacities respectively as follows: a single-layer copper trace (single copper) with a maximum thickness of 2.7 μm, a double-layer copper trace (dual copper) with maximum thicknesses of 2.7 μm and 0.9 μm respectively. Therefore, under trace manufacturing capacities of a usual glass substrate, if a Mini LED with high-voltage of 6V is used, the COG-substrate needs to be designed with a dual-copper trace solution, as shown in FIG. 2, in which six masks (i.e. six mask processes) are used for manufacturing of the base plate, so that a manufacturing cost of the base plate is high, resulting in high manufacturing costs and low cost-effectiveness of Mini LED backlight products based on a COG-substrate. Moreover, under process capacities of Cu trace on a usual glass-substrate base plate, if a Mini LED with high-voltage of 6V is used, products of some specification series may have Cu trace thicknesses of the base plate exceed specifications, failing to layout and develop a full range of COG-substrate Mini LED products.

Meanwhile, because a best efficiency point for a commonly used flip Mini LED is within 2 mA, the higher the operating current, the lower the luminous efficiency. The lower the photoelectric conversion efficiency of the Mini LED, the higher the power consumption of the back light unit (BLU), the more severe the heat generation of the lamp board, and the shorter the service life of the lamp board. Taking the Mini LED with high-voltage of 6V and with a dimension of 0916 as an example, it has a best efficiency point of 1 mA, and wall plug efficiency (WPE) of 64.26%. At 13.6 mA and 6.96 mA, values of WPE are respectively 53.1% and 58.4%. The LED at a high current of 13.6 mA has WPE 5.3% lower than that at a low current of 6.96 mA, and has efficiency 11.08% lower than the best efficiency point, leading to severe waste of light efficiency of the Mini LED.

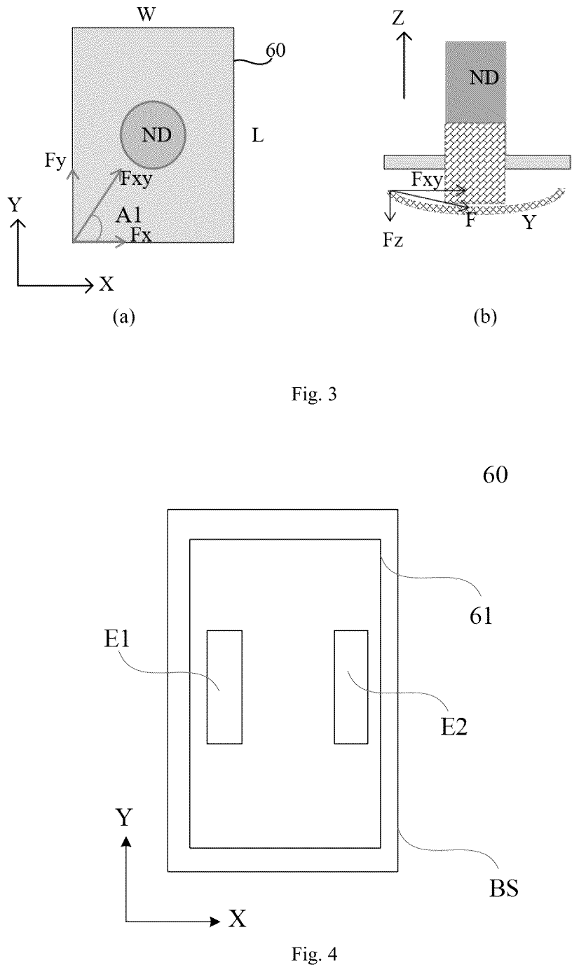

FIG. 3 is a schematic diagram of rotation during die bonding. As shown in FIG. 3, uneven force distribution of a light emitting device 60 in direction X and direction Y incurs rotation during die bonding. FIG. 4 shows a schematic diagram of the light emitting device 60. As shown in FIG. 4, the light emitting device 60 includes a base substrate BS, a light emitting unit 61 located on the base substrate BS, as well as an electrode E1 and an electrode E2 respectively connected with the light emitting unit 61. One of the electrode E1 and the electrode E2 may be referred to a P electrode, while the other of the electrode E1 and the electrode E2 may be referred to an N electrode.

FIG. 3 shows a pressing needle ND in a die bonding process; in the die bonding process, the pressing needle ND presses against the light emitting device 60. The light emitting device 60 shown in FIG. 3 has a length L, and a width W; in a case where the length L is greater than the width W, the light emitting device 60 is rectangular. Due to uneven force distribution of the light emitting device 60 in direction X and direction Y, rotation during die bonding is caused. Component forces of the light emitting device 60 in direction X and direction Y are respectively Fx and Fy; a combined force acting on the light emitting device 60 is Fxy, and an included angle between combined force Fxy and direction X is angle A1; and a force acting on the light emitting device 60 in direction Z is Fz. FIG. 3 (a) shows direction X and direction Y, and FIG. 3 (b) shows direction Z. For example, direction Y is perpendicular to direction X, and direction Z is perpendicular to direction X, and perpendicular to direction Y.

The mainstream Mini LEDs with dimensions of 0620, 0818 and 0916 are all rectangular with aspect ratios of approximately (1.8 to 3.3): 1, so the aspect ratios are relatively large. At the aspect ratio, during a die bonding process, uneven force distribution on the LED in direction X and direction Y will incur the problem of rotation during die bonding, resulting in a low manufacturing yield of Mini LED backlight related products and further increasing manufacturing costs of a COG-substrate Mini LED backlight. In addition, the larger the aspect ratio of the light emitting device (chip), the higher the occurrence rate of rotation during die bonding: a 0620 die with an aspect ratio of 3.3:1 has a rotation defect rate of 4%, and a 0916 die with an aspect ratio of 1.8:1 has a rotation defect rate of 2%. For example, the die bonding process may adopt a die bond mode in which the BP film is 1020R UV film, but it is not limited thereto.

For example, with respect to the existing Mini LED with high-voltage of 6V with dimensions 0620, 0818, 0916, etc., because the P electrode and the N electrode of the LED have smaller dimensions, in a case where a bump thickness is designed as 8 μm, insufficient pull-back of solder on the LED for the chip during the soldering process will further cause the problem of rotation during die bonding, thereby further increasing manufacturing costs of Mini LED related products.

Table 1 shows rotation during die bonding of Mini LEDs with dimensions 0916 and 0620. From Table 1, it can be seen that Mini LEDs with dimensions 0916 and 0620 have higher defect rates of rotation during die bonding.

TABLE 1
Rotation during die bonding of Mini
LEDs with dimensions 0916 and 0620

| Chip (light emitting | | Angle generation | |
|---|---|---|---|
| device) type | Quantity | rate | Specification |
| 0916 | 43 | 2% | ≤6° |
| 0620 | 124 | 4% | ≤6° |

Currently, as the global economy gradually shows a weak trend, consumers have become more sensitive to the price of Mini LED products. Meanwhile, from the perspective of industrial upgrading, if a price range of Mini LED upgraded and iterated products may be kept within 1.2 times that of the original products, it will promote large-scale replacement upgrades. Therefore, improving cost-effectiveness of Mini LED products is the top priority in promoting COG-substrate Mini LED backlight products and the key to seizing the lead in the Mini LED industry.

The light emitting device, the light emitting substrate, the backlight module, and the display apparatus provided by the embodiments of the present disclosure need to solve at least one of problems below.

### (1) High Manufacturing Costs of BP Dual-Cu Trace Design

In order to meet high brightness demand, the COG-substrate Mini LED with high-voltage of 6V has a higher operating current, so the COG-substrate needs a solution of dual-Cu trace design, causing high costs of BP manufacturing, which results in higher costs of products based on the COG-substrate Mini LED backlight, lower cost-effectiveness of the products, and slow progress of market promotion.

### (2) Failure to Develop a Full Range of COG-Substrate Mini LED Products as Limited by Process Capacities of Cu Trace on BP

On the existing glass-substrate BP, a single-copper trace has a maximum thickness of 2.7 μm, and a dual-copper trace has a maximum thickness of 3.6 μm; so the Cu trace thickness on the BP will exceed a specification in a case of a Mini LED with high-voltage of 6V, resulting in failure to design and develop some models of COG-substrate Mini LED products.

### (3) Rotation During Die Bonding Due to Large Aspect Ratio of LED

The mainstream high-voltage Mini LEDs with dimensions 0620, 0818 or 0916 are rectangular, with aspect ratios between 1.8:1 and 3.3:1, and the aspect ratios are relatively large. In the die bonding process, for example, in a die bond mode in which a BP film of 1020R, uneven force distribution on the LED in direction X and direction Y will incur the problem of rotation during die bonding. In addition, the larger the aspect ratio of the chip (the light emitting device), the higher the occurrence rate of rotation, resulting in a lower production yield of Mini LED backlight related products, thereby further increasing the manufacturing costs of COG-substrate Mini LED backlight.

### (4) Insufficient Pull-Back of Solder for Chip (Light Emitting Device) Due to Small Dimensions of P Electrode and N Electrode of LED

Usually in a Mini LED with high-voltage of 6V and with dimensions 0620, 0818 or 0916, in a case where a bump thickness is designed as 8 μm, pull-back of solder on the LED is in sufficient for the chip (the light emitting device) during the soldering process because dimensions of the P electrode and the N electrode of the LED are small, which further leads to the problem of rotation during die bonding. For example, the bump refers to a portion of the P electrode or the N electrode that is located above the topmost insulation layer.

With respect to the above-described four problems in the existing COG-substrate Mini LED backlight, the embodiments of the present disclosure provide a light emitting device, a light emitting substrate, a backlight module, and a display apparatus to solve at least one of the above-described problems.

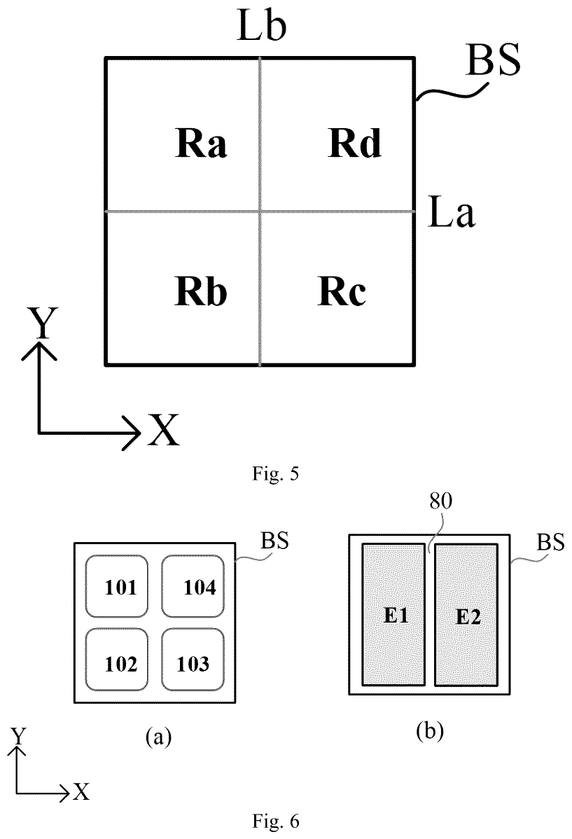

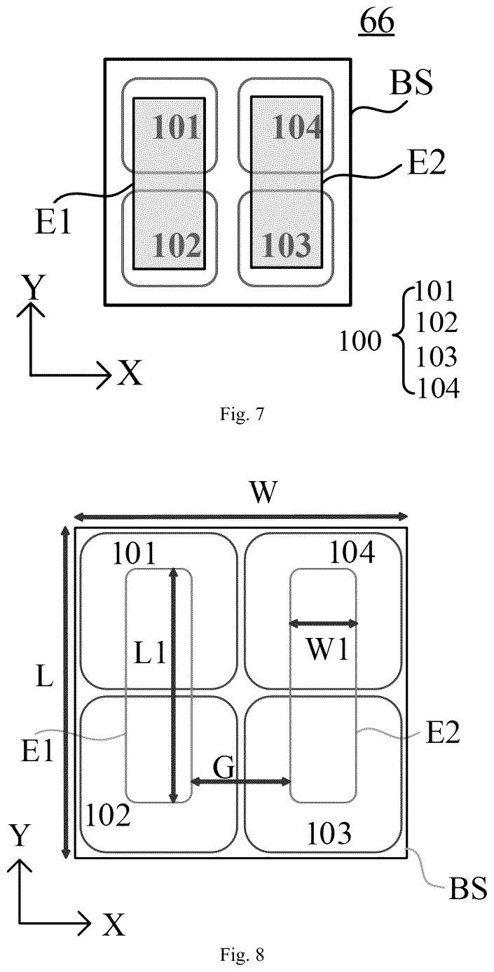

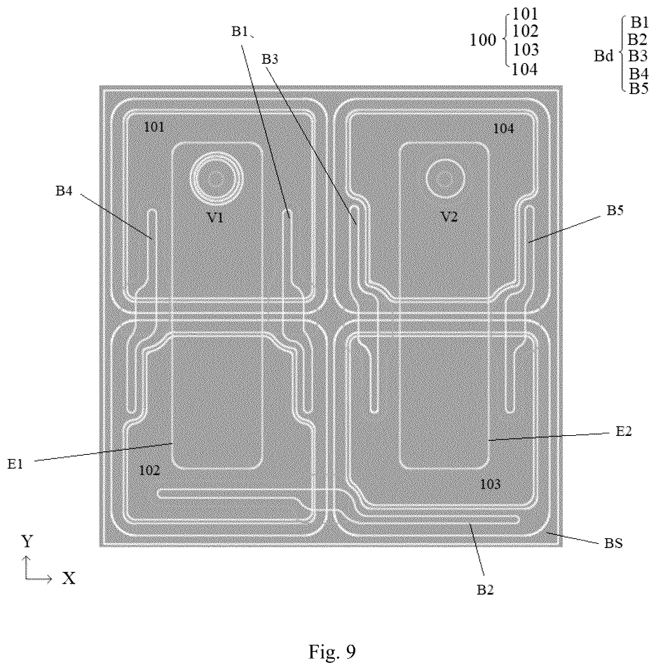

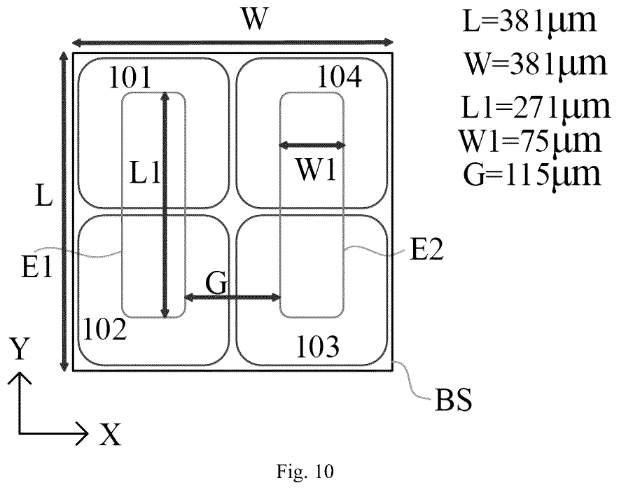

FIG. 5 is a schematic diagram of region partition of a light emitting device provided by an embodiment of the present disclosure. FIG. 6 is a schematic diagram of a light emitting unit, a first electrode and a second electrode in a light emitting device provided by an embodiment of the present disclosure. FIG. 7 is a schematic diagram of a light emitting device provided by an embodiment of the present disclosure. FIG. 8 is a schematic diagram of dimensioning of a light emitting device provided by an embodiment of the present disclosure. FIG. 9 is a layout diagram of a light emitting device provided by an embodiment of the present disclosure. FIG. 10 is a schematic diagram of a dimension of a light emitting device provided by an embodiment of the present disclosure.

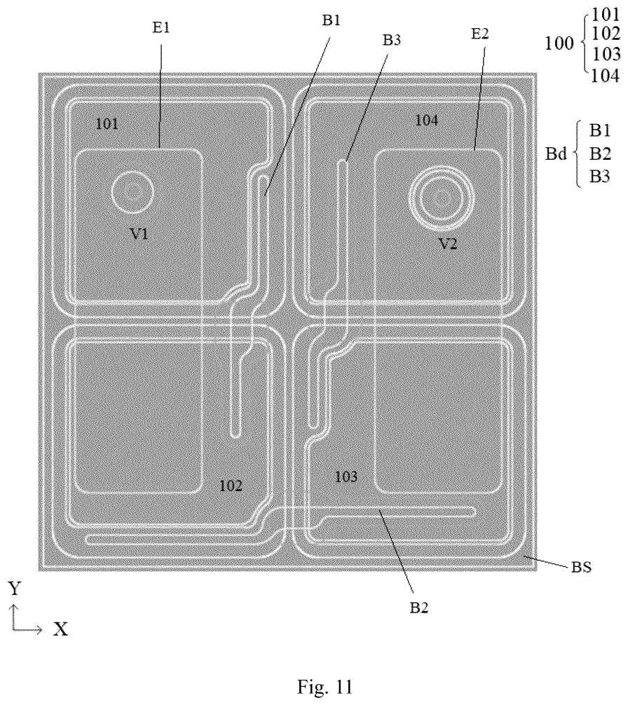

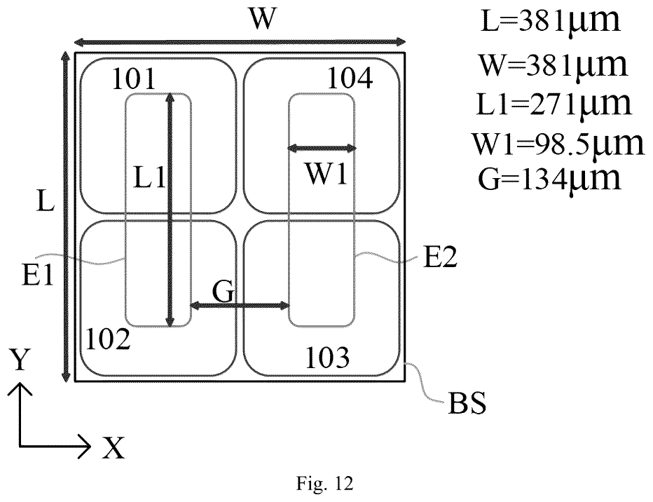

FIG. 11 is a layout diagram of a light emitting device provided by an embodiment of the present disclosure. FIG. 12 is a schematic diagram of a dimension of a light emitting device provided by an embodiment of the present disclosure.

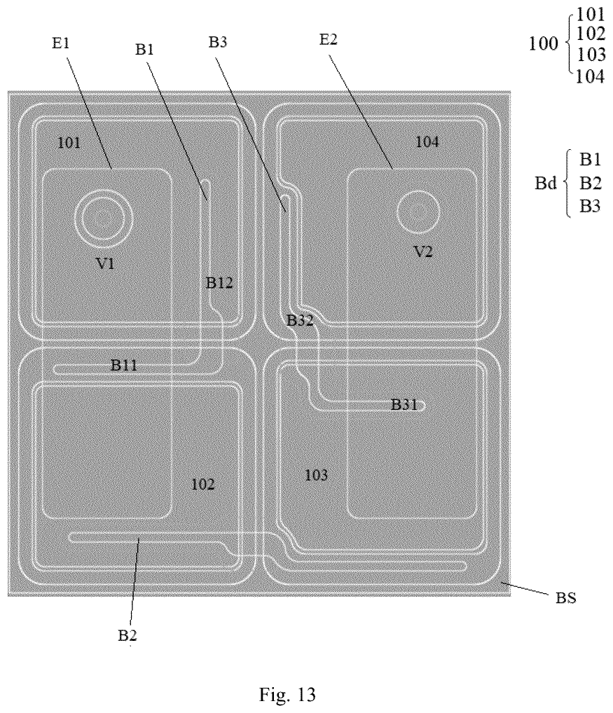

FIG. 13 is a layout diagram of a light emitting device provided by an embodiment of the present disclosure.

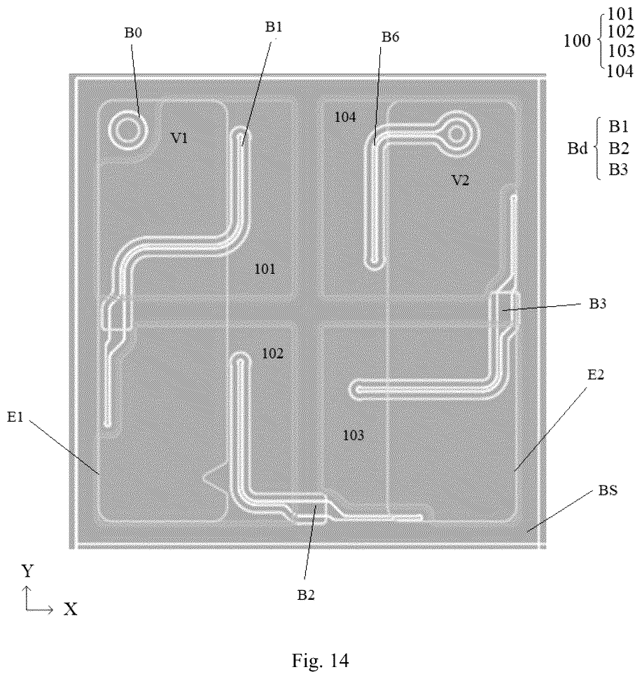

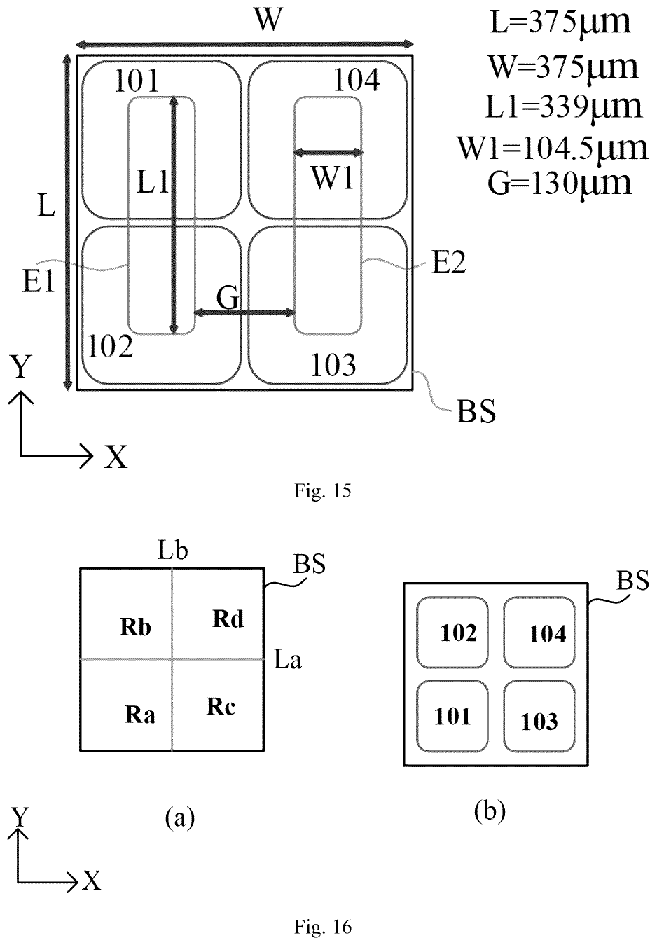

FIG. 14 is a layout diagram of a light emitting device provided by an embodiment of the present disclosure. FIG. 15 is a schematic diagram of a dimension of a light emitting device provided by an embodiment of the present disclosure.

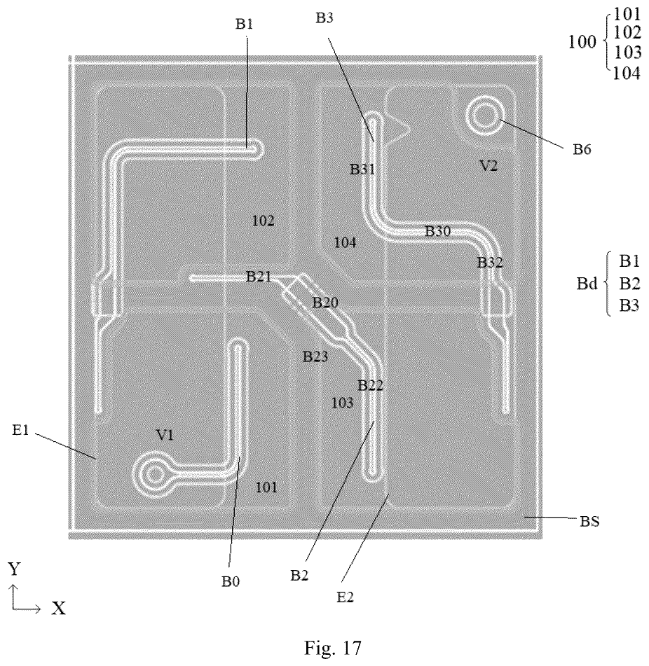

FIG. 16 is a schematic diagram of region partition of a light emitting device and a light emitting unit in the light emitting device provided by an embodiment of the present disclosure. FIG. 17 is a layout diagram of a light emitting device provided by an embodiment of the present disclosure.

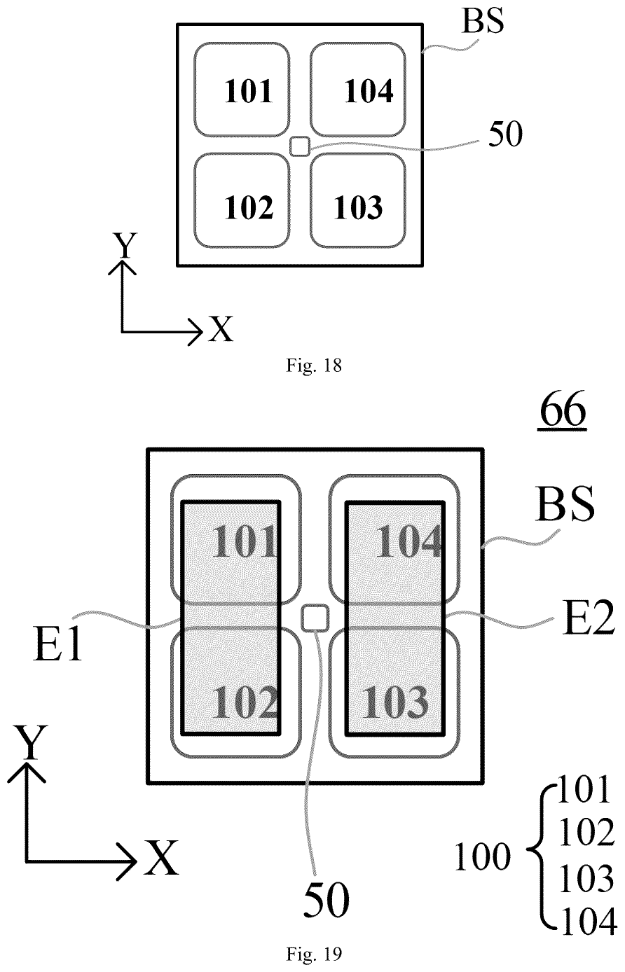

FIG. 18 is a schematic diagram of a light emitting device provided by an embodiment of the present disclosure. FIG. 19 is a schematic diagram of a light emitting device provided by an embodiment of the present disclosure.

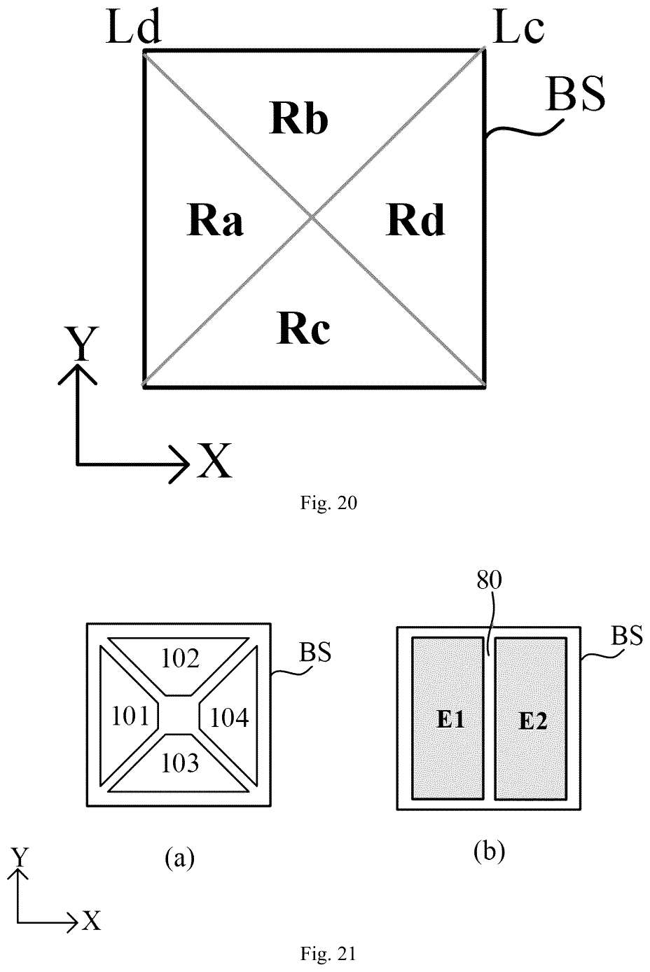

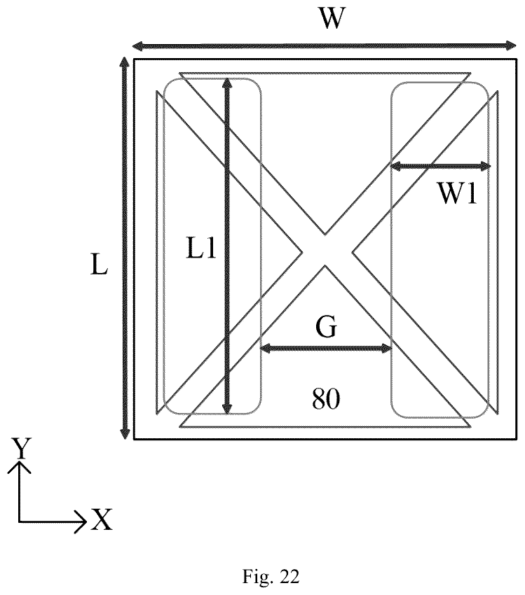

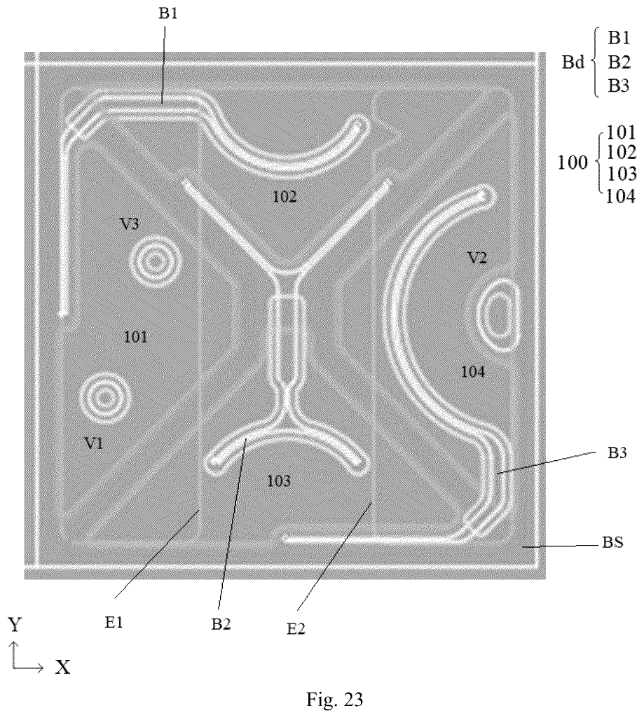

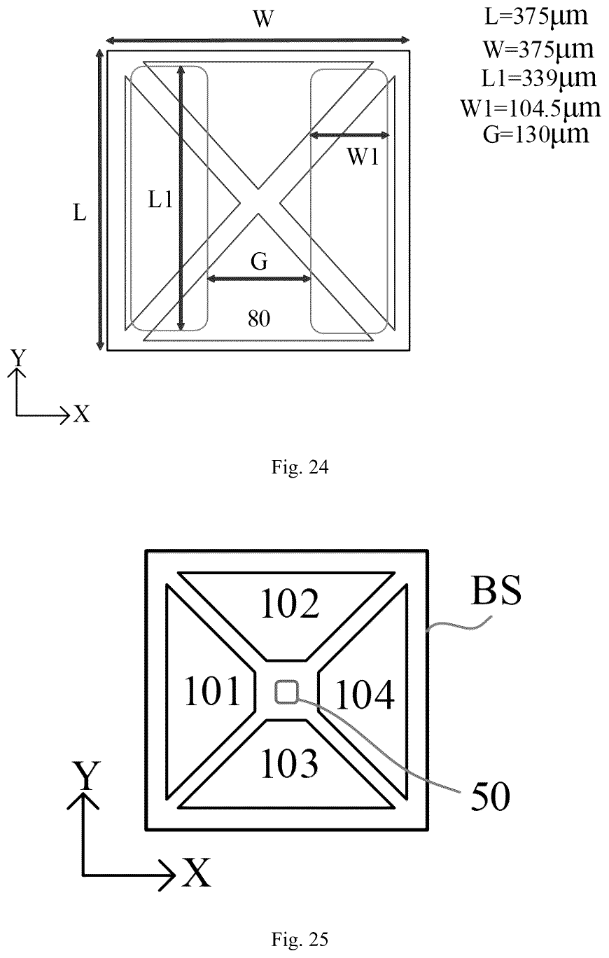

FIG. 20 is a schematic diagram of region partition of a light emitting device provided by an embodiment of the present disclosure. FIG. 21 is a schematic diagram of a light emitting unit, a first electrode and a second electrode in a light emitting device provided by an embodiment of the present disclosure. FIG. 22 is a schematic diagram of dimensioning of a light emitting device provided by an embodiment of the present disclosure. FIG. 23 is a layout diagram of a light emitting device provided by an embodiment of the present disclosure. FIG. 24 is a schematic diagram of a dimension of a light emitting device provided by an embodiment of the present disclosure.

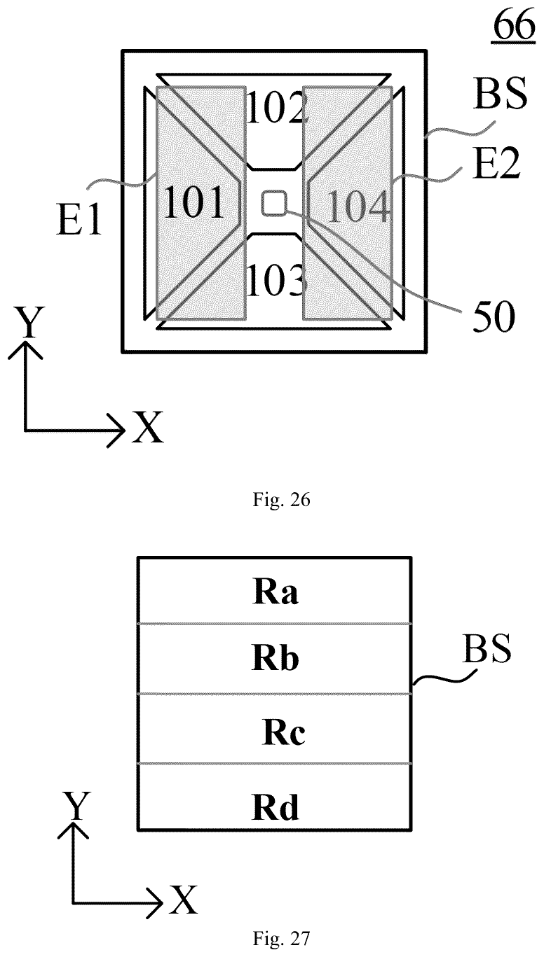

FIG. 25 is a schematic diagram of a light emitting device provided by an embodiment of the present disclosure. FIG. 26 is a schematic diagram of a light emitting device provided by an embodiment of the present disclosure.

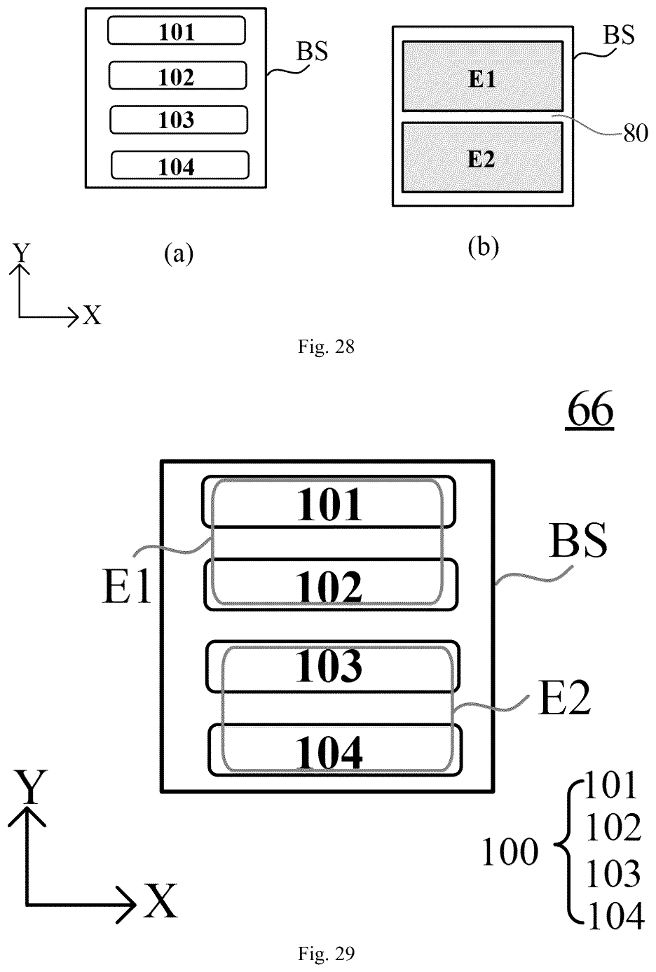

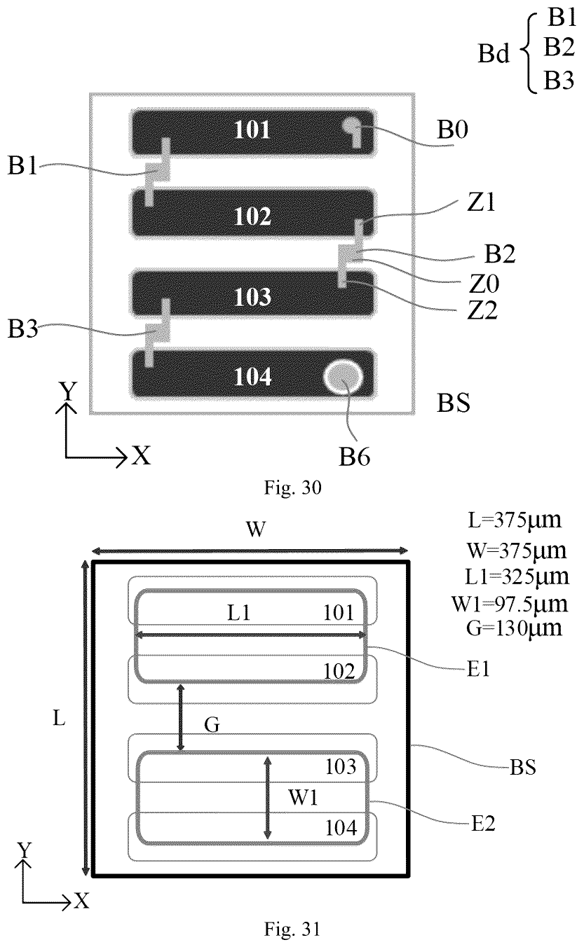

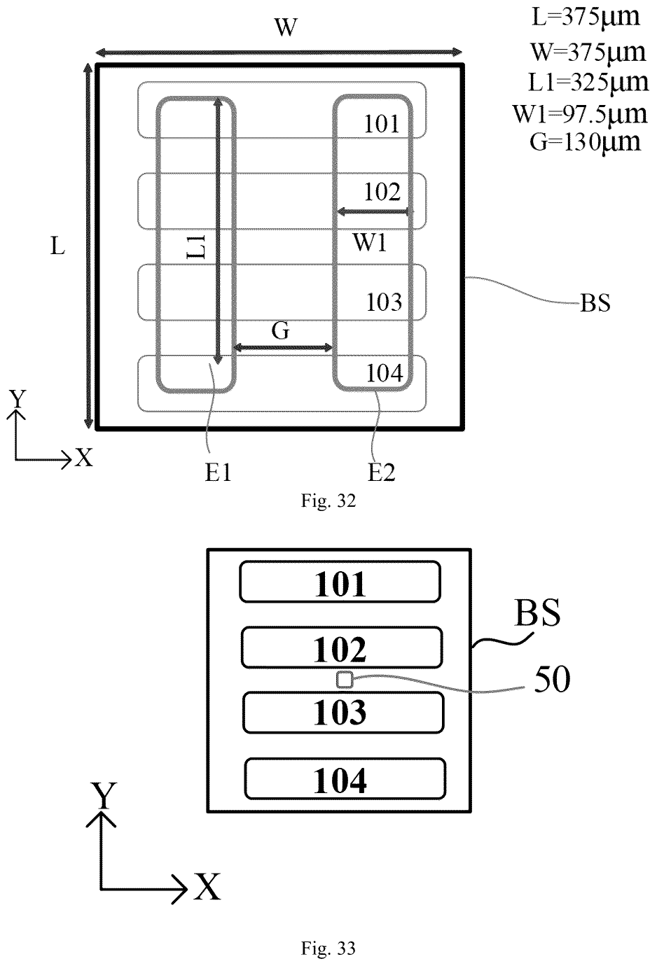

FIG. 27 is a schematic diagram of region partition of a light emitting device provided by an embodiment of the present disclosure. FIG. 28 is a schematic diagram of a light emitting unit, a first electrode and a second electrode in a light emitting device provided by an embodiment of the present disclosure. FIG. 29 is a schematic diagram of a light emitting device provided by an embodiment of the present disclosure. FIG. 30 is a layout diagram of a light emitting device provided by an embodiment of the present disclosure. FIG. 31 is a schematic diagram of a dimension of a light emitting device provided by an embodiment of the present disclosure. FIG. 32 is a schematic diagram of a structure and a dimension of a light emitting device provided by another embodiment of the present disclosure.

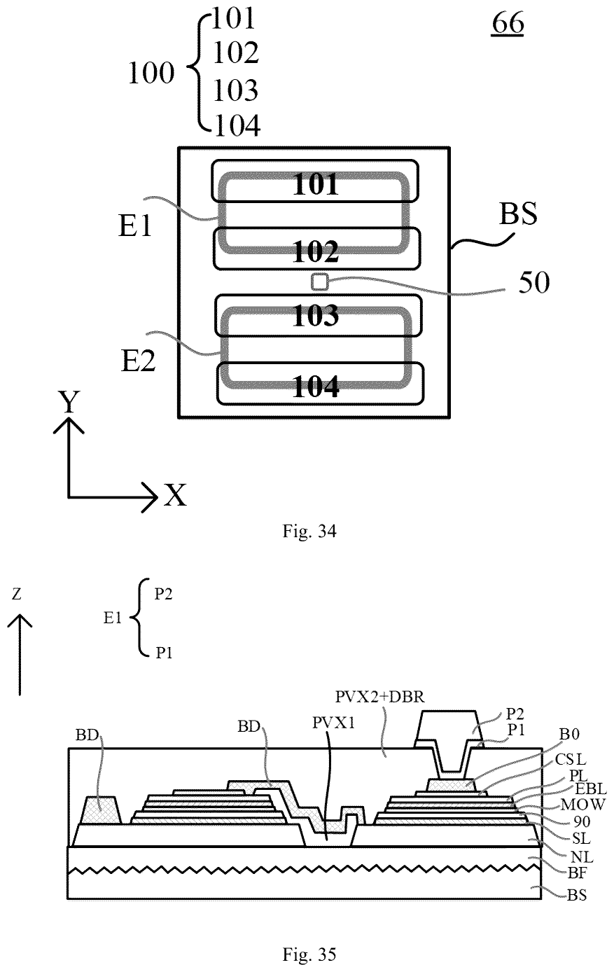

FIG. 33 is a schematic diagram of a light emitting device provided by an embodiment of the present disclosure. FIG. 34 is a schematic diagram of a light emitting device provided by an embodiment of the present disclosure.

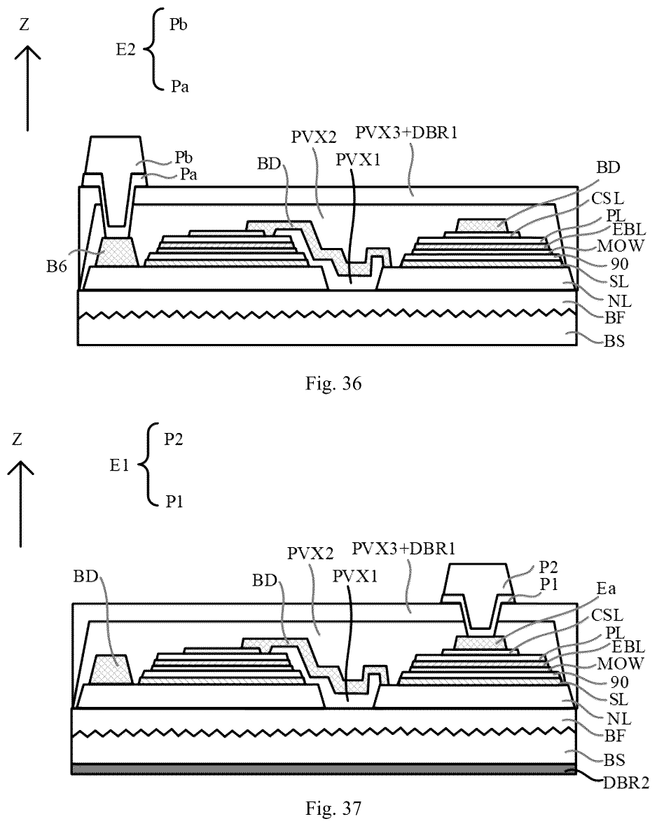

FIG. 35 is a cross-sectional view of a light emitting device provided by an embodiment of the present disclosure. FIG. 36 is a cross-sectional view of a light emitting device provided by another embodiment of the present disclosure. FIG. 37 is a cross-sectional view of a light emitting device provided by another embodiment of the present disclosure.

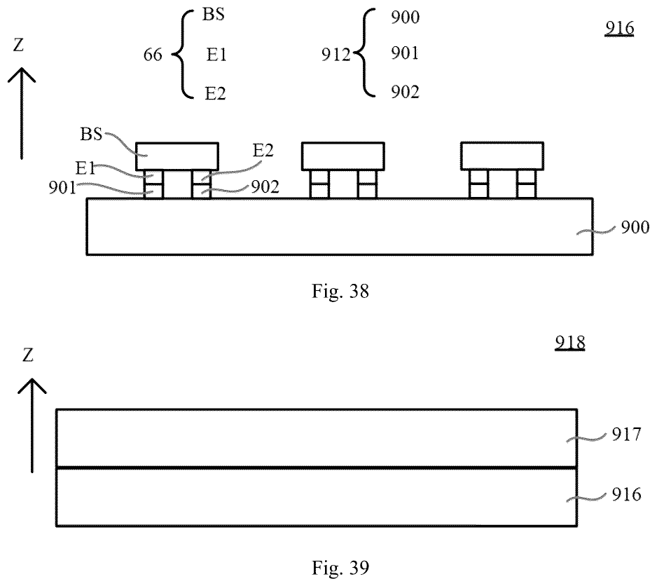

FIG. 38 is a schematic diagram of a light emitting substrate provided by an embodiment of the present disclosure. FIG. 39 is a schematic diagram of a display apparatus provided by an embodiment of the present disclosure.

Referring to FIG. 5 to FIG. 34, an embodiment of the present disclosure provides a light emitting device, including a base substrate BS, a plurality of light emitting units 100, a first electrode E1, a second electrode E2, and a bridge electrode BD. The plurality of light emitting units 100 are located on the base substrate BS and connected in series; the first electrode E1 is connected with one end of the plurality of light emitting units 100 connected in series; the second electrode E2 is connected with the other end of the plurality of light emitting units 100 connected in series; the bridge electrode BD is configured to connect two light emitting units 100 among the plurality of light emitting units 100; and the plurality of light emitting units 100 are configured to emit light under a pressure difference between the first electrode E1 and the second electrode E2.

Referring to FIG. 7 to FIG. 15, FIG. 17, FIG. 19, FIG. 22 to FIG. 24, FIG. 26, FIG. 29, FIG. 31 to FIG. 32 and FIG. 34, an orthographic projection of at least one of the first electrode E1 and the second electrode E2 on the base substrate BS overlaps with orthographic projections of at least two light emitting units 100 among the plurality of light emitting units 100 on the base substrate BS.

The embodiment of the present disclosure is illustrated by taking that an orthographic projection of at least one of the first electrode E1 and the second electrode E2 on the base substrate BS overlaps with orthographic projections of two or three light emitting units 100 on the base substrate BS as an example. The number of light emitting units 100 overlapping with the first electrode E1 or the second electrode E2 is not limited to two or three, which is related to the number of light emitting units in the light emitting device and an arrangement mode of the light emitting units in the light emitting device.

A light emitting device 66 provided by the embodiment of the present disclosure includes a plurality of light emitting units 100 connected in series; an orthographic projection of at least one of the first electrode E1 and the second electrode E2 overlaps with orthographic projections of at least two light emitting units 100 on the base substrate BS, so that at least one of the first electrode E1 and the second electrode E2 has a larger area, which is favorable for die bonding, so as to avoid insufficient pull-back of the solder for the light emitting device in the die bonding process, thereby avoiding or alleviating rotation during die bonding.

One light emitting device 66 provided by the embodiment of the present disclosure has a plurality of light emitting units 10 connected in series, so an operating current may be reduced for equivalent power, which is favorable for base plate manufacturing; for example, a conductive pattern layer (i.e., a single-Cu trace) may be used on the base plate to avoid cumbersome process in the case of a dual-Cu trace.

For example, as shown in FIG. 6 to FIG. 15, FIG. 17, FIG. 19, FIG. 21 to FIG. 24, FIG. 26, FIG. 29, FIG. 31 to FIG. 32, and FIG. 34, in the light emitting device, the first electrode E1 and the second electrode E2 are spaced apart from each other; the first electrode E1 and the second electrode E2 are arranged in direction X; each of the first electrode E1 and the second electrode E2 extends in direction Y; and direction X intersects with direction Y. FIG. 6, FIG. 22 and FIG. 28 show a gap 80 between the first electrode E1 and the second electrode E2. The first electrode E1 and the second electrode E2 are spaced apart from each other in a plan view, to be separated.

In some accompanying drawings of the embodiments of the present disclosure, a plan view shows direction X and direction Y, and a cross-sectional view shows direction Z. Direction Y and Direction X are both directions parallel with a main surface of the base substrate BS. Direction Z is a direction perpendicular to the main surface of the base substrate BS. For example, direction Y intersects with direction X. The embodiment of the present disclosure is illustrated by taking that direction Y is perpendicular direction X as an example. The main surface of the base substrate BS is a surface for forming the light emitting unit.

As shown in FIG. 8, FIG. 10, FIG. 12, FIG. 15, FIG. 22, FIG. 24, and FIG. 31 to FIG. 32, a length of the base substrate BS is L, a width of the base substrate BS is W, a length of the first electrode E1 is L1, a width of the first electrode E1 is W1, and a dimension of the second electrode E2 may be the same as or different from the dimension of the first electrode E1. The embodiment of the present disclosure is illustrated by taking that the first electrode E1 and the second electrode E2 have the same dimension as an example.

For example, as shown in FIG. 8, FIG. 10, FIG. 12, FIG. 15, FIG. 22, FIG. 24, FIG. 31 to FIG. 32, in the light emitting device, a ratio of a maximum dimension of the base substrate BS in direction X to a maximum dimension of the base substrate BS in direction Y is (1 to 1.18): 1.

For example, as shown in FIG. 8, FIG. 10, FIG. 12, FIG. 15, FIG. 22, FIG. 24, FIG. 31 to FIG. 32, in the light emitting device, a ratio of a maximum dimension of the plurality of light emitting units 100 in direction X to a maximum dimension of the plurality of light emitting units 100 in direction Y is (1 to 1.18): 1.

In the light emitting device provided by the embodiment of the present disclosure, the dimension of the light emitting device or the light emitting unit in the light emitting device is adjusted to (1 to 1.18): 1, so that the light emitting device is a square or an approximate square, thereby effectively alleviating the problem of rotation during die bonding. In a case where the dimension of the light emitting unit in the light emitting device is 1:1, the problem of rotation during die bonding can be more effectively alleviated.

Table 2 shows force distributions of Mini LEDs with different dimensions; and it can be seen from Table 2 that the design of reducing the aspect ratio design of the Mini LED may effectively reduce the problem of rotation during die bonding.

TABLE 2
force distributions of Mini LEDs with different dimensions

| Chip | Aspect ratio | Angle A1 | Maximum force | Minimum force |
|---|---|---|---|---|
| Square | 1 | 45° | 1 | 1 |
| 1021 | 2 | 63.4° | 1.26 | 0.63 |
| 0620 | 3.4 | 73.6° | 1.36 | 0.4 |

For example, as shown in FIG. 10, FIG. 12, FIG. 15, FIG. 24, FIG. 31 to FIG. 32, in the light emitting device, a ratio of a maximum dimension of each of the first electrode E1 and the second electrode E2 in direction X to a maximum dimension of the base substrate BS in direction X is greater than 19%.

For example, as shown in FIG. 10, FIG. 12, FIG. 15, FIG. 24, FIG. 31 to FIG. 32, in the light emitting device, a ratio of a maximum dimension of each of the first electrode E1 and the second electrode E2 in direction X to a maximum dimension of the plurality of light emitting units 100 in direction X is greater than 19%.

In the light emitting device provided by the embodiment of the present disclosure, the first electrode E1 and the second electrode E2 have a larger proportion in direction X, to have a larger area.

For example, in the light emitting device, a ratio of a dimension of each of the first electrode E1 and the second electrode E2 in direction X to a maximum dimension of the plurality of light emitting units 100 in direction X is less than or equal to 26%.

In the light emitting device provided by the embodiment of the present disclosure, a ratio of a dimension of each of the first electrode E1 and the second electrode E2 in direction X to a maximum dimension of the plurality of light emitting units 100 or the base substrate BS in direction X is defined, to facilitate obtaining the first electrode E1 and the second electrode E2 with a larger width, and to facilitate layout design of the first electrode E1 and the second electrode E2.

As shown in FIG. 10, in the light emitting device, a ratio of a maximum dimension W1 of each of the first electrode E1 and the second electrode E2 in direction X to a maximum dimension W of the base substrate BS in direction X is W1/W, W1/W=75 μm/381 μm=19.6%, a numerical value greater than 19%. The maximum dimension of the plurality of light emitting units 100 in direction X is less than the maximum dimension of the base substrate BS in direction X, so a ratio of a maximum dimension of each of the first electrode E1 and the second electrode E2 in direction X to the maximum dimension of the plurality of light emitting units 100 in direction X is greater than 19.6%, a numerical value greater than 19%.

As shown in FIG. 12, in the light emitting device, a ratio of a maximum dimension W1 of each of the first electrode E1 and second electrode E2 in direction X to the maximum dimension W of the base substrate BS in direction X is W1/W, W1/W=98.5 μm/381 μm=25.8%, a numerical value greater than 19%. The maximum dimension of the plurality of light emitting units 100 in direction X is less than the maximum dimension of the base substrate BS in direction X, so a ratio of a maximum dimension of each of the first electrode E1 and the second electrode E2 in direction X to the maximum dimension of the plurality of light emitting units 100 in direction X is greater than 25.8%, a numerical value greater than 19%.

As shown in FIG. 15 and FIG. 24, in the light emitting device, a ratio of a maximum dimension W1 of each of the first electrode E1 and the second electrode E2 in direction X to the maximum dimension W of the base substrate BS in direction X is W1/W, W1/W=104.5 μm/375 μm=25.8%, a numerical value greater than 19%. The maximum dimension of the plurality of light emitting units 100 in direction X is less than the maximum dimension of the base substrate BS in direction X, so a ratio of a maximum dimension of each of the first electrode E1 and the second electrode E2 in direction X to the maximum dimension of the plurality of light emitting units 100 in direction X is greater than 25.8%, a numerical value greater than 19%.

As shown in FIG. 31 and FIG. 32, in the light emitting device, a ratio of a maximum dimension W1 in each of the first electrode E1 and second electrode E2 in direction X to the maximum dimension W of the base substrate BS in direction X is W1/W, W1/W=97.5 μm/375 μm=26%, a numerical value greater than 19%. The maximum dimension of the plurality of light emitting units 100 in direction X is less than the maximum dimension of the base substrate BS in direction X, so a ratio of a maximum dimension of each of the first electrode E1 and the second electrode E2 in direction X to the maximum dimension of the plurality of light emitting units 100 in direction X is greater than 26%, a numerical value greater than 19%.

For example, in the light emitting device, there is a gap 80 between the first electrode E1 and the second electrode E2; and a ratio of a minimum dimension of the gap in direction X to a maximum dimension of the base substrate BS in direction X is greater than or equal to 30% and less than or equal to 35%.

For example, in the light emitting device, there is a gap 80 between the first electrode E1 and the second electrode E2; and a ratio of the minimum dimension of the gap in direction X to the maximum dimension of the plurality of light emitting units 100 in direction X is greater than or equal to 30% and less than or equal to 35%.

As shown in FIG. 10, in the light emitting device, a ratio of a minimum dimension of the gap 80 in direction X to the maximum dimension of the plurality of light emitting units 100 in direction X is G/W, G/W=115 μm/381 μm=30%, a numerical value greater than or equal to 30% and less than or equal to 35%.

As shown in FIG. 12, in the light emitting device, a ratio of a minimum dimension of gap 80 in direction X to the maximum dimension of the plurality of light emitting units 100 in direction X is G/W, G/W=134 μm/381 μm=35%, a numerical value greater than or equal to 30% and less than or equal to 35%.

As shown in FIG. 15, FIG. 24, FIG. 31, and FIG. 32, in the light emitting device, a ratio of the minimum dimension of gap 80 in direction X to the maximum dimension of the plurality of light emitting units 100 in direction X is G/W, G/W=130 μm/375 μm=35%, a numerical value greater than or equal to 30% and less than or equal to 35%.

In the light emitting device provided by the embodiment of the present disclosure, a ratio of the minimum dimension of the gap in direction X to the maximum dimension of the base substrate BS or the plurality of light emitting units 100 in direction X is defined, to facilitate obtaining a larger gap, and obtaining the first electrode E1 and the second electrode E2 with a larger width, and to facilitate layout design of the first electrode E1 and the second electrode E2.

Referring to FIG. 5 to FIG. 19, the base substrate BS is partitioned into four regions through a midline La and a midline Lb; the four regions include region Ra, region Rb, region Rc, and region Rd; each region is provided with a light emitting unit 100; and FIG. 5 to FIG. 19 are illustrated by taking that four light emitting units are arranged on the base substrate BS as an example. For example, the midline La may be referred to as a horizontal midline, and the midline Lb may be referred to as a vertical midline.

Referring to FIG. 20 to FIG. 26, the base substrate BS is partitioned into four regions through a diagonal line Lc and a diagonal line Ld; the four regions include region Ra, region Rb, region Rc, and region Rd; each region is provided with a light emitting unit 100; and FIG. 20 to FIG. 26 are illustrated by taking that four light emitting units are arranged on the base substrate BS as an example.

Referring to FIG. 27 to FIG. 32, the base substrate BS is partitioned into four regions in direction Y; the four regions include region Ra, region Rb, region Rc, and region Rd; each region is provided with a light emitting unit 100; and FIG. 27 to FIG. 32 are illustrated by taking that four light emitting units are arranged on the base substrate BS as an example.

The embodiment of the present disclosure is illustrated by taking that four light emitting units are arranged on the base substrate BS as an example. It should be noted that four or more light emitting units may be arranged on the base substrate BS.

For example, referring to FIG. 5 to FIG. 32, in the light emitting device, the plurality of light emitting units 100 include a first light emitting unit 101, a second light emitting unit 102, a third light emitting unit 103, and a fourth light emitting unit 104; and the bridge electrode BD includes a first bridge electrode B1, a second bridge electrode B2, and a third bridge electrode B3.

For example, referring to FIG. 5 to FIG. 32, in the light emitting device, the first light emitting unit 101 and the second light emitting unit 102 are connected through the first bridge electrode B1, the second light emitting unit 102 and the third light emitting unit 103 are connected through the second bridge electrode B2, and the third light emitting unit 103 and the fourth light emitting unit 104 are connected through the third bridge electrode B3.

For example, as shown in FIG. 9, FIG. 11 and FIG. 13, in the light emitting device, at least a portion of the first bridge electrode B1 and at least a portion of the third bridge electrode B3 are located between the first electrode E1 and the second electrode E2; the second bridge electrode B2 extends in direction X and is located on a side where short edges of the first electrode E1 and the second electrode E2 are located.

For example, as shown in FIG. 9, FIG. 11 and FIG. 13, in the light emitting device, the bridge electrode BD is located within an outer contour of the region where the first electrode E1 and the second electrode E2 are located. For example, an outer contour of the region where the first electrode E1 and the second electrode E2 are located is rectangular, but it is not limited thereto.

For example, as shown in FIG. 9 and FIG. 11, in the light emitting device, each of the first bridge electrode B1 and the third bridge electrode B3 extends in direction Y; and an orthographic projection of each of the first bridge electrode B1 and the third bridge electrode B3 on the base substrate BS does not overlap with the orthographic projections of the first electrode E1 and the second electrode E2 on the base substrate BS.

For example, as shown in FIG. 13, in the light emitting device, each of the first bridge electrode B1 and the third bridge electrode B3 includes a first portion extending in direction X and a second portion extending in direction Y; orthographic projections of the first portion B11 of the first bridge electrode B1 and the first portion B31 of the third bridge electrode B3 on the base substrate BS respectively overlap with the orthographic projections of the first electrode E1 and the second electrode E2 on the base substrate BS; an orthographic projection of the second portion B12 of the first bridge electrode B1 on the base substrate BS does not overlap with the orthographic projection of the first electrode E1 on the base substrate BS; and an orthographic projection of the second portion B32 of the third bridge electrode B3 does not overlap with the orthographic projection of the second electrode E2 on the base substrate BS. Through design of folding the bridge electrode inward, the dimension of the gap, the area of the first electrode E1, and the area of the second electrode E2 are increased, resulting in better offset tolerance and better pushing force during die bonding.

For example, as shown in FIG. 9, in the light emitting device, the bridge electrode BD further includes a fourth bridge electrode B4 and a fifth bridge electrode B5; the first light emitting unit 101 and the second light emitting unit 102 are also connected through the fourth bridge electrode B4; the third light emitting unit 103 and the fourth light emitting unit 104 are also connected through the fifth bridge electrode B5; the fourth bridge electrode B4 and the first bridge electrode B1 are located on both sides of the first electrode E1; and the fifth bridge electrode B5 and the second bridge electrode B2 are located on both sides of the second electrode E2.

For example, referring to FIG. 5 to FIG. 15, in the light emitting device, the substrate is rectangular; the first light emitting unit 101, the second light emitting unit 102, the third light emitting unit 103, and the fourth light emitting unit 104 are respectively located within four regions partitioned by the two midlines of the rectangle; the first light emitting unit 101 and the second light emitting unit 102 are arranged in direction Y; the third light emitting unit 103 and the fourth light emitting unit 104 are arranged in direction Y; the first light emitting unit 101 and the fourth light emitting unit 104 are arranged in direction X; and the second light emitting unit 102 and the third light emitting unit 103 are arranged in direction X.

For example, as shown in FIG. 14, the first bridge electrode B1 is Z-shaped; the second bridge electrode B2 is L-shaped; and the third bridge electrode B3 is L-shaped.

For example, as shown in FIG. 16 and FIG. 17, in the light emitting device, the substrate is rectangular; the first light emitting unit 101, the second light emitting unit 102, the third light emitting unit 103, and the fourth light emitting unit 104 are respectively located in four regions partitioned by the two midlines of the rectangle; the first light emitting unit 101 and the second light emitting unit 102 are arranged in direction Y; the third light emitting unit 103 and the fourth light emitting unit 104 are arranged in direction Y; the first light emitting unit 101 and the third light emitting unit 103 are arranged in direction X; and the second light emitting unit 102 and the fourth light emitting unit 104 are arranged in direction X. As shown in FIG. 17, the second bridge electrode B2 includes an inclined portion B20; and the inclined portion 20 is inclined relative to direction X and inclined relative to direction Y.

For example, as shown in FIG. 17, in the light emitting device, the third bridge electrode B3 has a middle portion B30 extending in direction X and portions located on both sides of the middle portion B30 and both extending in direction Y. FIG. 17 shows a portion B31 and a portion B32 located on both sides of the middle portion B30.

For example, as shown in FIG. 17, in the light emitting device, the second bridge electrode B2 has an opening B23; the opening B23 faces the first light emitting unit 101. Each of the portions (the first portion B21 and the second portion B22) located on both sides of the inclined portion B20 has an obtuse included angle with the inclined portion B20. That is, the first portion B21 has an obtuse included angle with the inclined portion B20; and the second portion B22 has an obtuse included angle with the inclined portion B20. The inclined portion B20, the first portion B21, and the second portion B22 form the opening B23 facing the first light emitting unit 101.

For example, as shown in FIG. 17, in the light emitting device, the second bridge electrode B2 is C-shaped.

For example, as shown in FIG. 17 and FIG. 30, in the light emitting device, the bridge electrode BD further includes a connection electrode B0; and an orthographic projection of the connection electrode B0 on the base substrate BS is located within an orthographic projection of the first light emitting unit 101 on the base substrate BS.

For example, as shown in FIG. 17 and FIG. 30, in the light emitting device, the bridge electrode BD further includes a connection electrode B6; and an orthographic projection of the connection electrode B6 on the base substrate BS is located within an orthographic projection of the fourth light emitting unit 104 on the base substrate BS.

For example, as shown in FIG. 20 to FIG. 26, in the light emitting device, the substrate is rectangular; the first light emitting unit 101, the second light emitting unit 102, the third light emitting unit 103, and the fourth light emitting unit 104 are respectively located in four regions partitioned by two diagonals of the rectangle; the first light emitting unit 101 and the fourth light emitting unit 104 are arranged in direction X; the second light emitting unit 102 and the third light emitting unit 103 are arranged in direction Y; and the second bridge electrode B2 passes through an intersection of the two diagonals; the design in which the bridge electrode spans across the intersection increases a current spreading effect, reduces a light shading effect of the bridge electrode, and has higher light efficiency.

For example, as shown in FIG. 23, in the light emitting device, at least one of the first bridge electrode B1, the second bridge electrode B2, and the third bridge electrode B3 has a bent portion. As shown in FIG. 23, the first bridge electrode B1, second bridge electrode B2, and third bridge electrode B3 each have a bent portion.

For example, as shown in FIG. 27 to FIG. 34, in the light emitting device, the first light emitting unit 101, the second light emitting unit 102, the third light emitting unit 103, and the fourth light emitting unit 104 are arranged in direction Y; the first bridge electrode B1 and the second bridge electrode B2 are respectively arranged on both sides of the second light emitting unit 102 in direction X; and the second bridge electrode B2 and the third bridge electrode B3 are respectively arranged on both sides of the third light emitting unit 103 in direction X.

For example, as shown in FIG. 30, in the light emitting device, at least one of the first bridge electrode B1, the second bridge electrode B2, and the third bridge electrode B3 is Z-shaped. As shown in FIG. 30, the first bridge electrode B1, second bridge electrode B2, and third bridge electrode B3 each are Z-shaped.

For example, as shown in FIG. 30, the Z-shaped bridge electrode includes a middle portion Z0, as well as a first portion Z1 and a second portion Z2 respectively located on both sides of the middle portion Z0 and respectively connected with two ends of the middle portion Z0.

For example, as shown in FIG. 30, the first portion Z1 extends in direction Y; and the second portion Z2 extends in direction Y. For example, as shown in FIG. 30, the middle portion Z0 extends in direction X.

For example, as shown in FIG. 18, FIG. 19, FIG. 25, FIG. 26, FIG. 33, and FIG. 34, the light emitting device further includes a damage preventing structure 50; the damage preventing structure 50 is located within a region surrounded by the first light emitting unit 101, the second light emitting unit 102, the third light emitting unit 103, and the fourth light emitting unit 104; and no conductive structure is provided within a region where the damage preventing structure 50 is located. The damage preventing structure 50 is provided to avoid damaging the light emitting device during the die bonding process.

In the light emitting device provided by the embodiment of the present disclosure, an electrical isolation region is provided at an intersection of the horizontal midline and the vertical midline of the Mini LED. In a case where a needle-type die bonder is used to transfer the LED to a driving substrate, when the pressing needle presses against the surface where the first electrode E1 and second electrode E2 of the LED are located, the pressing needle of the die bonder may cause damage to the first electrode E1 and second electrode E2 of the LED, thereby causing electrical abnormalities of the LED. To prevent damage to the LED during the manufacturing process, the damage preventing structure 50 is added to the middle portion. In such design, a middle region where the damage preventing structure 50 is located is an electrical isolation region. Through electrical isolation measures, even if the position is damaged, it will not cause electrical abnormalities in the LED.

For example, as shown in FIG. 35 to FIG. 37, in the light emitting device, a thickness of each of the first electrode E1 and the second electrode E2 is greater than or equal to 8 μm.

For example, as shown in FIG. 35 to FIG. 37, in the light emitting device, a thickness of each of the first electrode E1 and the second electrode E2 is less than or equal to 15 μm.

As shown in FIG. 35 and FIG. 37, the first electrode E1 may include a first electrode portion P1 and a second electrode portion P2. For example, a material of the second electrode portion P2 includes solder, for example, tin solder. The first electrode portion P1 and the second electrode portion P2 are made of different materials. The material of the first electrode portion P1 includes metal. For further example, the metals in the first electrode portion P1 include gold (Au), aluminum (Al), platinum (Pt), titanium (Ti), nickel (Ni), etc.

For example, the material of the bridge electrode BD includes metal. For further example, the metal in the bridge electrode BD includes copper.

For example, the first electrode portion P1 and the second electrode portion P2 have different thicknesses. Usually, a thickness of the first electrode portion P1 is less than a thickness of the second electrode portion P2.

As shown in FIG. 36, the second electrode E2 may include a first electrode portion Pa and a second electrode portion Pb. For example, the material of the second electrode portion Pb includes solder, for example, tin solder. The first electrode portion Pa and the second electrode portion Pb are made of different materials. The material of the first electrode portion Pa includes metal. For example, the metals in the first electrode Pa include gold (Au), aluminum (Al), platinum (Pt), titanium (Ti), nickel (Ni), etc.

For example, the material of the bridge electrode BD includes metal. For further example, the metal in the bridge electrode BD includes copper.

For example, the first electrode portion Pa and the second electrode portion Pb have different thicknesses. Usually, the thickness of the first electrode portion Pa is less than the thickness of the second electrode portion Pb.

For example, as shown in FIG. 36 to FIG. 37, the light emitting device further includes a passivation layer PVX1, a passivation layer PVX2, and a passivation layer PVX3; the bridge electrode BD is located on the passivation layer PVX1; the passivation layer PVX2 is located on the bridge electrode BD; the passivation layer PVX3 is located on the passivation layer PVX2; and the passivation layer PVX3 also serves as a distributed Bragg reflector DBR1.

For example, as shown in FIG. 37, in order to increase a flare angle, the light emitting device further includes a distributed Bragg reflector film layer DBR2; the distributed Bragg reflector film layer DBR2 is located on a side of the base substrate BS that is not provided with a plurality of light emitting units 100.

The light emitting device provided by the embodiment of the present disclosure may be a 12-V high-voltage Mini LED, but it is not limited thereto. If a voltage component of one light emitting unit is 3 V, then a voltage difference between two ends of the four light emitting units can be 12 V.

In the light emitting device provided by the embodiment of the present disclosure, the plurality of light emitting units are connected in series; and the four light emitting units may be arranged in three modes as follows: a 2*2 array (as shown in FIG. 5 to FIG. 19), a ring (as shown in FIG. 20 to FIG. 26), and a 1*4 array (as shown in FIG. 27 to FIG. 32).

In the light emitting device provided by the embodiment of the present disclosure, the light emitting unit 100 may have a shape of rectangle, square, and triangle (trapezoid).

FIG. 5 to FIG. 19 show that the light emitting units 100 are four rectangles arranged in a 2*2 array, with a horizontal midline and a vertical midline of the light emitting device as a dividing reference.

FIG. 20 to FIG. 26 show that the light emitting units 100 are four triangles arranged in a 1:1:1:1 ring pattern, with two diagonal lines of the light emitting device as a dividing reference of the light emitting units.

FIG. 27 to FIG. 32 show that the light emitting units 100 are four rectangles arranged in a 1*4 array, with a ¼ horizontal line of the light emitting device as a dividing reference of the light emitting units. A bottom surface of the 12-V high-voltage Mini LED is a surface where the first electrode E1 and the second electrode E2 of the Mini LED are located, and includes two structures: a positive electrode P (a P electrode) and a negative electrode N (an N electrode); and there is a gap between the P electrode and the N electrode to prevent an electrical short circuit.

As shown in FIG. 9 and FIG. 10, the light emitting device may be a 12-V high-voltage Mini LED; the light emitting device has an outer dimension of 381 μm*381 μm; the gap 80 has a dimension G of 115 μm; and the first electrode E1 and the second electrode E2 both have a dimension of 271 μm*75 μm. The layout adopts the mode in which four rectangular light emitting units 100 are arranged in a 2*2 array, with a horizontal midline and a vertical midline of the Mini LED as a dividing reference of the light emitting units. The four rectangular light emitting units 100 are connected by five misaligned long-strip bridge electrodes. The first bridge electrode B1, the fourth bridge electrode B4, the third bridge electrode B3, and the fifth bridge electrode B5 are the four misaligned long-strip bridge electrodes. The first bridge electrode B1 and the fourth bridge electrode B4 are located on both sides, i.e., a left side and a right side, of the first electrode E1; and the third bridge electrode B3 and the fifth bridge electrode B5 are located on both sides, i.e., a left side and a right side, of the second electrode E2, and are parallel with a long edge direction of the first electrode E1 or the second electrode E2, i.e. parallel with direction Y. The first bridge electrode B1 and the fourth bridge electrode B4 are both used for connecting the first light emitting unit 101 and the second light emitting unit 102; and the third bridge electrode B3 and the fifth bridge electrode B5 are both used for connecting the third light emitting unit 103 and the fourth light emitting unit 104. The long-strip second bridge electrode B2 is located at the bottom of the layout, and is parallel with short edge directions of the first electrode E1 and the second electrode E2, respectively, i.e., parallel with direction X. The second bridge electrode B2 is used for connecting the second light emitting unit 102 and the third light emitting unit 103. The layout design is relatively symmetrical left and right, so that the first electrode E1 and second electrode E2 with a larger area may be obtained. However, as compared with other light emitting devices provided by the embodiments of the present disclosure, the dimension of the gap, the area of the first electrode E1, and the area of the second electrode E2 are relatively small, and the layout design is suitable for scenarios with low requirements on die bond offset and pushing force; a design value of the P electrode and the N electrode on the corresponding base plate (BP) is 311 μm*115 μm; and a design value of the gap between the P electrode and the N electrode on the corresponding base plate (BP) is 135 μm, but it is not limited thereto.

As shown in FIG. 11 and FIG. 12, the light emitting device may be a 12-V high-voltage Mini LED; the light emitting device has an outer dimension of 381 μm*381 μm; the gap 80 has a dimension G of 134 μm; and the first electrode E1 and the second electrode E2 both have a dimension of 271 μm*98.5 μm. The layout adopts the mode in which four rectangular light emitting units 100 are arranged in a 2*2 array, with a horizontal midline and a vertical midline of the Mini LED as a dividing reference of the light emitting units. The four rectangular light emitting units 100 are connected by three misaligned long-strip bridge electrodes. Two misaligned long-strip bridge electrodes, that is, the first bridge electrode B1 and the third bridge electrode B3 are located between the first electrode E1 and the second electrode E2, and are parallel with long edge directions of the first electrode E1 and the second electrode E2, respectively. The first bridge electrode B1 is used for connecting the first light emitting unit 101 and the second light emitting unit 102; and the third bridge electrode B3 is used for connecting the third light emitting unit 103 and the fourth light emitting unit 104. The long-strip second bridge electrode B2 is located at the bottom of the layout, is parallel with short edge directions of the first electrode E1 and the second electrode E2, respectively, and is used for connecting the second light emitting unit 102 and the third light emitting unit 103. The layout design increases the dimension of the gap, the area of the first electrode E1, and the area of the second electrode E2 by reducing the number of bridge electrodes. The layout is concise and has good left-right symmetry, and can increase offset tolerance of die bond and improve pushing force of the LED; a design value of the P electrode and the N electrode on the corresponding base plate (BP) is 311 μm*138.5 μm; and a design value of the gap between the P electrode and the N electrode on the corresponding base plate (BP) is 154 μm.

As shown in FIG. 12 and FIG. 13, the light emitting device may be a 12-V high-voltage Mini LED; the light emitting device has an outer dimension of 381 μm*381 μm; the gap 80 has a dimension G of 134 μm; and the first electrode E1 and the second electrode E2 both have a dimension of 271 μm*98.5 μm. The layout adopts the mode in which four rectangular light emitting units 100 are arranged in a 2*2 array, with a horizontal midline and a vertical midline of the Mini LED as a dividing reference of the light emitting units. The four rectangular light emitting units 100 are connected by two L-shaped bridge electrodes and one misaligned long-strip bridge electrode. The two L-shaped bridge electrodes, that is, the first bridge electrode B1 and the third bridge electrode B3, are located between the first electrode E1 and the second electrode E2, and are located on an upper portion of the LED, with openings both facing an outer side of the LED. The first bridge electrode B1 is used for connecting the first light emitting unit 101 and the second light emitting unit 102; and the third bridge electrode B3 is used for connecting the third light emitting unit 103 and the fourth light emitting unit 104. The misaligned long-strip second bridge electrode B2 is located at the bottom of the layout, parallel with short edge directions of the first electrode E1 and the second electrode E2, respectively, and is used for connecting the second light emitting unit 102 and the third light emitting unit 103. The layout design increases the dimension of the gap, the area of the first electrode E1, and the area of the second electrode E2 by folding the bridge electrodes inward, has advantages of better offset tolerance and better pushing force. However, the layout is more complex and less symmetrical, and is only applicable to scenarios with relatively loose requirements for optical symmetry; a design value of the P electrode and the N electrode on the corresponding base plate (BP) is 311 μm*138.5 μm; and a design value of the gap between the P electrode and the N electrode on the corresponding base plate (BP) is 154 μm.

As shown in FIG. 14 and FIG. 15, the light emitting device may be a 12-V high-voltage Mini LED; the light emitting device has an outer dimension of 375 μm*375 μm; the gap 80 has a dimension G of 130 μm; and the first electrode E1 and the second electrode E2 both have a dimension of 339 μm*104.5 μm. The layout adopts the mode in which four rectangular light emitting units 100 are arranged in a 2*2 array, with a horizontal midline and a vertical midline of the Mini LED as a dividing reference of the light emitting units. The four rectangular light emitting units 100 are connected by two L-shaped bridge electrodes and one Z-shaped bridge electrode. Each of the two L-shaped bridge electrodes, that is, the second bridge electrode B2 and the third bridge electrode B3, spans across two light emitting units 100; the second bridge electrode B2 is used for connecting the second light emitting unit 102 and the third light emitting unit 103; and the third bridge electrode B3 is used for connecting the third light emitting unit 103 and the fourth light emitting unit 104. The connection electrode B6 is an L-shaped connection electrode B0, located only within the fourth light emitting unit 104. The connection electrode B6 is located inside the first light emitting unit 101. The first bridge electrode B1 is used for connecting the first light emitting unit 101 and the second light emitting unit 102. An orthographic projection of the Z-shaped first bridge electrode B1 on the base substrate BS overlaps with an orthographic projection of the first electrode E1 on the base substrate BS; the Z-shaped first bridge electrode B1 spans across the first light emitting unit 101 and the second light emitting unit 102, a portion of the first bridge electrode B1 that is located inside the first light emitting unit 101 is L-shaped and has an opening facing an upper left corner; while a portion of the first bridge electrode B1 that is located inside the second light emitting unit 102 is located at the edge, presenting a straight line shape, and is parallel with long edge directions of the first electrode E1 and the second electrode E2, respectively. The layout design further increases the areas of the first electrode E1 and the second electrode E2 by folding the bridge electrodes inward, and is suitable for scenarios with high requirements on pushing force and low requirements on optical symmetry; a design value of the P electrode and the N electrode on the corresponding base plate (BP) is 379 μm*144.5 μm; and a design value of the gap between the P electrode and the N electrode on the corresponding base plate (BP) is 150 μm.

As shown in FIG. 14 and FIG. 15, the light emitting device may be a 12-V high-voltage Mini LED; the light emitting device has an outer dimension of 375 μm*375 μm; the gap 80 has a dimension G of 130 μm; and the first electrode E1 and the second electrode E2 both have a dimension of 339 μm*104.5 μm. The layout adopts the mode in which four rectangular light emitting units 100 are arranged in a 2*2 array, with a horizontal midline and a vertical midline of the Mini LED as a dividing reference of the light emitting units. The four rectangular light emitting units 100 are connected by one L-shaped bridge electrode, one Z-shaped bridge electrode, and one C-shaped bridge electrode. The L-shaped first bridge electrode spans across two light emitting units 100 and is used for connecting the first light emitting unit 101 and the second light emitting unit 102. The L-shaped connection electrode B0 is located only within the first light emitting unit 101. For example, the connection electrode B0 is connected with the first electrode E1. An orthographic projection of the Z-shaped third bridge electrode B3 on the base substrate BS overlaps with an orthographic projection of the second electrode E2 on the base substrate BS, and the Z-shaped third bridge electrode B3 spans across the third light emitting unit 103 and the fourth light emitting unit 104; a portion of the third bridge electrode B3 that is located inside the fourth light emitting unit 104 is L-shaped and has an opening facing an upper right corner; and a portion of the third bridge electrode B3 that is located inside the third light emitting unit 103 is located at an edge, presenting a straight line shape, and is parallel with long edge directions of the first electrode E1 and the second electrode E2, respectively. The C-shaped second bridge electrode B2 passes through an intersection of the horizontal midline and the vertical midline, and is located at a lower edge of the second light emitting unit 102 and on a left side inside the third light emitting unit 103. The layout in which the bridge electrode spans across the intersection increases a current spreading effect, reduces a light shading effect of the bridge electrode, and has higher light efficiency; a design value of the P electrode and the N electrode on the corresponding base plate (BP) is 379 μm*144.5 μm; and a design value of the gap between the P electrode and the N electrode on the corresponding base plate (BP) is 150 μm.

As shown in FIG. 23 and FIG. 24, the light emitting device may be a 12-V high-voltage Mini LED; the light emitting device has an outer dimension of 375 μm*375 μm; the gap 80 has a dimension G of 130 μm; and the first electrode E1 and the second electrode E2 both have a dimension of 339 μm*104.5 μm. The layout adopts the mode in which four triangular light emitting units 100 are arranged in a 1:1:1:1 ring pattern, with a left diagonal and a right diagonal of the Mini LED as a dividing reference of the light emitting units. The four triangular light emitting units 100 are connected by two L-shaped plus arc-shaped bridge electrode and one Y-shaped plus arc-shaped bridge electrode. The L-shaped plus arc-shaped first bridge electrode B1 in an upper left corner spans across the first light emitting unit 101 and the second light emitting unit 102, and is used for connecting the first light emitting unit 101 and the second light emitting unit 102. The L-shaped plus arc-shaped third bridge electrode B3 in an lower right corner spans across the third light emitting unit 103 and the fourth light emitting unit 104, and is used for connecting the third light emitting unit 103 and the fourth light emitting unit 104. The Y-shaped plus arc-shaped second bridge electrode B2 spans across the second light emitting unit 102 and the third light emitting unit 103, and is used for connecting the second light emitting unit 102 and the third light emitting unit 103. The layout increases a current spreading effect through the design of the Y-shaped plus arc-shaped bridge electrode (the second bridge electrode B2) in the middle, and has better optical symmetry; but has slightly lower light efficiency due to more light shading by the bridge electrode; a design value of the P electrode and the N electrode on the corresponding base plate (BP) is 379 μm*144.5 μm; and a design value of the gap between the P electrode and the N electrode on the corresponding base plate (BP) is 150 μm.

As shown in FIG. 30 and FIG. 31, the light emitting device may be a 12-V high-voltage Mini LED; the light emitting device has an outer dimension of 375 μm*375 μm; the gap 80 has a dimension G of 130 μm; and the first electrode E1 and the second electrode E2 both have a dimension of 325 μm*97.5 μm. The layout adopts the mode in which four rectangular light emitting units 100 are arranged in a 1*4 array, with a ¼ horizontal line of the Mini LED as a dividing reference of the light emitting units. The four rectangular light emitting units 100 are connected by three Z-shaped bridge electrodes. The two Z-shaped bridge electrodes, that is, the first bridge electrode B1 and the third bridge electrode B3 are located on a left side of the LED; the first bridge electrode B1 is used for connecting the first light emitting unit 101 and the second light emitting unit 102; and the third bridge electrode B3 is used for connecting the third light emitting unit 103 and the fourth light emitting unit 104. The Z-shaped second bridge electrode B2 on the right side connects the second light emitting unit 102 and the third light emitting unit 103. The layout design is concise, with a simple manufacturing process, and less light shading, but poor optical symmetry and a poor current spreading effect; a design value of the P electrode and the N electrode on the corresponding base plate (BP) is 365 μm*117.5 μm; and a design value of the gap between the P electrode and the N electrode on the corresponding base plate (BP) is 150 μm.

The first electrode E1 and the second electrode E2 in FIG. 28, FIG. 29, and FIG. 31 are arranged in direction Y; and the first electrode E1 and the second electrode E2 in FIG. 32 are arranged in direction X. The arrangement mode of the first electrode E1 and the second electrode E2 as shown in FIG. 31 is more suitable for the layout shown in FIG. 30. The arrangement mode of the bridge electrodes in the light emitting device shown in FIG. 32 may be different from the mode shown in FIG. 30; and it is the best to avoid electrical problems.

In the embodiment of the present disclosure, the outer dimension of the light emitting device may be a dimension of the base substrate BS.

In the light emitting device provided by the embodiment of the present disclosure, as shown in FIG. 11, FIG. 13, FIG. 14, FIG. 17 and FIG. 23, the first electrode E1 is connected with the connection electrode B0 through a via hole V1; and the second electrode E2 is connected with the connection electrode B6 through a via hole V2.

As shown in FIG. 23, the first electrode E1 is also connected with the connection electrode B0 through a via hole V3.

The structure of the light emitting device will be described below in conjunction with FIG. 35 to FIG. 37.

The internal structure of the light emitting device provided by the embodiment of the present disclosure may be as shown in FIG. 35 to FIG. 37.

The light emitting device provided by the embodiment of the present disclosure may be a high-voltage Mini LED with a small aspect ratio and an outer dimension of 380*380±30 μm, and is a 15*15-mil 12-V high-voltage LED chip.

As shown in FIG. 35 to FIG. 37, the light emitting device includes a base substrate BS, a buffer layer BF located on the base substrate BS, an N-type layer NL located on the buffer layer BF, a super lattice layer SL located on the N-type layer NL, an N-type layer 90 located on the super lattice layer SL, a multiple quantum well layer MQW located on the N-type layer 90, an electron blocking layer EBL located on the multiple quantum well layer MQW, a P-type layer PL located on the electron blocking layer EBL, and a current spreading layer (CSL) located on the P-type layer PL; and a conductive pattern layer provided on the current spreading layer (CSL); the conductive pattern layer includes a connection electrode B0, a connection electrode B6, and a bridge electrode BD; and the bridge electrode BD is located on the passivation layer PVX1.

As shown in FIG. 35, the conductive pattern layer is provided thereon with a passivation layer PVX2; the passivation layer PVX2 may simultaneously serve as a distributed Bragg reflector DBR; the passivation layer PVX2 is provided thereon with an electrode layer; the electrode layer includes a first electrode E1 and a second electrode E2. Such structure is a regular-angle LED, which, paired with different layout designs as described above, is suitable for products with higher optical density (OD) and smaller pitch.

As shown in FIG. 36 to FIG. 37, the conductive pattern layer is provided thereon with a passivation layer PVX2; the passivation layer PVX2 is provided thereon with a passivation layer PVX3; the passivation layer PVX3 may simultaneously serve as a distributed Bragg reflector DBR; the passivation layer PVX3 is provided thereon with an electrode layer; and the electrode layer includes a first electrode E1 and a second electrode E2.

For example, the base substrate BS may include a sapphire substrate, but it is not limited thereto. The base substrate BS may be a patterned sapphire substrate (PSS).

For example, the N-type layer NL includes an N-type semiconductor. For example, a material of the N-type semiconductor includes N—GaN, but it is not limited thereto.

For example, the P-type layer PL includes a P-type semiconductor. For example, a material of the P-type semiconductor includes P—GaN, but it is not limited thereto.

FIG. 36 shows a 12-V high-voltage Mini LED added with an ALD protection layer for high reliability performance. For example, with respect to the light emitting device shown in FIG. 36, in a process of fabricating the passivation layer PVX2 by using a PECVD technology, due to limitations in process capacities, the passivation layer PVX2 serving as an insulation layer may have small cracks; in a humid and energized state, metal ions on the internal electrode, for example, Au ions, are difficult to bind with OH-ions and are constantly attracted by negative potential, travelling along the Bragg reflector DBR from the internal electrode to the external electrode, forming a conductive channel between the internal electrode and the external electrode, causing leakage and resulting in defects of LED dimming or black out. In the embodiment of the present disclosure, leakage refers to conduction in a non-conductive position, forming a short circuit. As shown in FIG. 36. In order to improve the defects of LED dimming or black out, a passivation layer PVX2 may be added between the passivation layer PVX1 and the outermost passivation layer on the basis of the structure shown in FIG. 35, forming a structure PVX with three passivation layers, that is, the passivation layer PVX1, the passivation layer PVX2, and the passivation layer PVX3 (the Bragg reflector DBR). For example, the passivation layer PVX2 shown in FIG. 36 is made of silica material and may be fabricated by using an atomic layer deposition (ALD) machine; the passivation layer PVX2 is located between the internal electrode and the external electrode, isolating the internal electrode and the external electrode, which may block a short circuit caused by migration of metal ions in the electrode and improve reliability of the light emitting device. In the embodiment of the present disclosure, the internal electrode refers to a conductive portion covered by the insulation layer, for example, the internal electrode refers to the bridge electrode; and the external electrode refers to the first electrode E1 or the second electrode E2.

FIG. 37 shows a structure of a large-angle 12-V high-voltage Mini LED, which, as compared with the structure of the light emitting device shown in FIG. 36, has a Bragg reflector film layer DBR2 on a side of the base substrate BS that is not provided with a light emitting unit. For example, the Bragg reflector film layer DBR2 is a laminated structure of silicon dioxide and titanium dioxide; and a light distribution curve of the LED may be adjusted through different film system designs. Light emitted by the light emitting device shown in FIG. 35 and the light emitting device shown in FIG. 36 have a shape approximate to that of a Lambertian body, with an angle of about 140° at a position of 50% light decay. Light emitted by a high-voltage Mini LED corresponding to the light emitting device shown in FIG. 37 has a shape of wing, with an angle of about 155° to 165° at a position of 50% light decay. The large-angle LED of such structure, combined with different layout designs, is suitable for products with smaller OD and larger pitch.

It should be noted that the respective film layer structures in the light emitting unit are not limited to those shown in the diagrams, and may be adjusted as needed.

An embodiment of the present disclosure further provides a light emitting substrate, including any of the above-described light emitting devices. As shown in FIG. 38, a light emitting substrate 916 includes a driving substrate 912 and a light emitting device 66; the light emitting substrate 916 is provided with an electrode 901 and an electrode 902; the first electrode E1 in the light emitting device 66 is connected with the electrode 901; and the second electrode E2 in the light emitting device 66 is connected with the electrode 902. One of the electrode 901 and the electrode 902 is a P electrode in the driving substrate 912, and the other of the electrode 901 and the electrode 902 is an N electrode in the driving substrate 912. For example, the driving substrate 912 may be a glass substrate, but it is not limited thereto. The driving substrate 912 may also be a printed circuit board (PCB).

For example, the driving substrate 912 may include organic resin materials such as epoxy resin, triazine, silicone resin, or polyimide. In some exemplary embodiments, the driving substrate 912 may be an FR4-type printed circuit board (PCB) or a flexible PCB that is prone to deformation. In some exemplary embodiments, the driving substrate 912 may include ceramic materials such as silicon nitride, AlN, Al₂O₃, or metals or metal compounds; and the driving substrate 912 may be, for example, a metal core printed circuit board (MCPCB) or a metal copper-clad laminate (MCCL).

An embodiment of the present disclosure further provides a backlight module, including any of the above-described light emitting substrates. The light emitting substrate 916 may serve as a backlight module for application in a liquid crystal display apparatus.

An embodiment of the present disclosure further provides a display apparatus, including any of the above-described backlight modules. As shown in FIG. 39, the display apparatus 918 includes a display panel 917 and a light emitting substrate 916 serving as a backlight module.

The light emitting device, the light emitting substrate, the backlight module, and the display apparatus provided by the embodiments of the present disclosure may implement a solution of a low-cost glass-substrate Mini LED backlight based on a high-voltage Mini LED with a small aspect ratio. Unlike the existing 6-V high-voltage Mini LED, in the light emitting device, the light emitting substrate, the backlight module and the display apparatus provided by the embodiments of the present disclosure, the high-voltage Mini LED may be a 12-V high-voltage Mini LED with an aspect ratio of (1 to 1.18): 1, which can have a layout design and a structural design that are different from usual Mini LEDs; and through corresponding processes, high-performance low-cost Mini LED backlight products based on such high-voltage Mini LEDs may be produced.

In the embodiments of the present disclosure, the layout of the light emitting device is adjusted to implement a first electrode E1 and a second electrode E2 having a larger area.

In the embodiments of the present disclosure, the structure of the light emitting device is adjusted, to implement at least one of performances such as damage prevention, and enlarged flare angle, etc.

The embodiments of the present disclosure can significantly improve cost-effectiveness of the Mini LED backlight products, so that COG-substrate Mini LEDs can overcome the disadvantage of higher costs than the PCB, while having technical advantages; can play an important role in promoting COG-substrate Mini LED backlight products to seize the lead in the Mini LED industry, and can be widely used in a full range of Mini LED backlight products such as commercial displays, TV, monitor (MNT), notebook (NB), vehicle-mounted displays, and virtual reality displays, etc.

The light emitting device, the light emitting substrate, the backlight module, and the display apparatus provided by the embodiments of the present disclosure have at least one of advantageous technical effects as follows.

(1) By increasing a driving voltage of the Mini LED, design requirements on trace thickness (Cu thickness) on the glass substrate can be reduced while meeting peak brightness requirements of the module; so single-layer trace can meet the requirements. For example, the dual-Cu trace requirement on the BP can be simplified to a single-Cu trace, and meanwhile, the mask process of the BP is simplified from 6 mask processes to 2 mask processes. By simplifying the trace thickness (Cu thickness) and the mask process, manufacturing costs of the BP are reduced, thereby improving cost-effectiveness of the COG-substrate Mini LED backlight products. According to evaluation, a combination of the 12-V high-voltage Mini LED and the high-voltage integrated circuit (IC) can reduce the cost by $50 under the 1K partition solution, as compared with the existing solution of the 6-V high-voltage Mini LED.

(2) Through the high-voltage design, an operating current of the Mini LED is reduced, so that the operating current of the Mini LED is closer to the best efficiency point of the LED when the backlight module operates normally, which improves photoelectric conversion efficiency of the LED and reduces light efficiency loss of the device. Meanwhile, it can alleviate the heating problem, lower power consumption of the lamp board (the backlight module), and thus improve service life of the lamp board.

(3) By designing the outer shape of the LED as a square, the aspect ratio is reduced from (1.8 to 3.3): 1 to an optimal (1 to 1.18): 1, which avoids the problem of rotation during die bonding caused by a large aspect ratio, and improves a manufacturing yield of the Mini LED backlight related products.

(4) Through the design of increasing the outer dimension of the LED, the dimensions of the P electrode and the N electrode of the LED is increased; under the design with a bump thickness of 8 μm, a solder volume of the bump increases, which avoids the problem of rotation during die bonding caused by insufficient pull-back of insufficient solder on the LED during the soldering process, further improves a manufacturing yield of the backlight module, and further reduces manufacturing costs of the COG-substrate Mini LED backlight.

(5) Through design of different layouts and structures, specific brightness, power consumption, quality, anti-static (ESD), and reliability requirements of various types of COG based Mini LED products are met with focuses.

(6) Through structure design of a plurality of light emitting units connected in series, one LED is equivalent to four LEDs integrated, which simplifies the traditional design of one region with four lamps to the design of one region with one lamp. Under the same partition design, the total number of LEDs on the backlight module is reduced, which can not only reduce the bill of material (BOM) of raw materials, but also reduce time for die bond, thereby improving a yield of one die bond, reducing a proportion of repair, and improving manufacturing efficiency.

(7) By using a 12-V high-voltage Mini LED composed of a plurality of light emitting units connected in series, the operating current can be reduced, and Cu thickness requirements can be reduced, which solves the problem of failure to design and develop some models of COG-substrate Mini LED products as Cu trace thickness on the BP exceeds a specification.

(8) Through design of different bump materials and optical film layers, design requirements of Mini LED products with different partitions, ODs, and pitches can be met, which provides possibilities for development and research as well as plan of diversified, multi-series, and multi-mode product models.

For example, in other embodiments, the above-described Mini LED can also be replaced with a Micro LED.

What have been described above are only specific implementations of the present disclosure, the protection scope of the present disclosure is not limited thereto. Any changes or substitutions easily occur to those skilled in the art within the technical scope of the present disclosure should be covered in the protection scope of the present disclosure. Therefore, the protection scope of the present disclosure should be based on the protection scope of the claims.

1. A light emitting device, comprising:
a base substrate;
a plurality of light emitting units, located on the base substrate and connected in series;
a first electrode, connected with one end of the plurality of light emitting units connected in series;
a second electrode, connected with the other end of the plurality of light emitting units connected in series; and
a bridge electrode, connecting two light emitting units among the plurality of light emitting units;
wherein an orthographic projection of at least one of the first electrode and the second electrode on the base substrate overlaps with orthographic projections of at least two light emitting units among the plurality of light emitting units on the base substrate.

2. The light emitting device according to claim 1, wherein the first electrode and the second electrode are spaced apart from each other, the first electrode and the second electrode are arranged in a first direction, each of the first electrode and the second electrode extends in a second direction, and the first direction intersects with the second direction.

3. The light emitting device according to claim 2, wherein a ratio of a maximum dimension of the base substrate in the first direction to a maximum dimension of the base substrate in the second direction is (1 to 1.18): 1, and/or
wherein a ratio of a maximum dimension of the plurality of light emitting units in the first direction to a maximum dimension of the plurality of light emitting units in the second direction is (1 to 1.18): 1.

4. (canceled)

5. The light emitting device according to claim 2, wherein a ratio of a maximum dimension of each of the first electrode and the second electrode in the first direction to a maximum dimension of the plurality of light emitting units in the first direction is greater than 19%, and/or
wherein the ratio of the maximum dimension of each of the first electrode and the second electrode in the first direction to the maximum dimension of the plurality of light emitting units in the first direction is less than or equal to 26%.

6. (canceled)

7. The light emitting device according to claim 2, wherein a gap is provided between the first electrode and the second electrode, and a ratio of a minimum dimension of the gap in the first direction to a maximum dimension of the plurality of light emitting units in the first direction is greater than or equal to 30% and less than or equal to 35%.

8. (canceled)

9. The light emitting device according to claim 2, wherein the plurality of light emitting units comprise a first light emitting unit, a second light emitting unit, a third light emitting unit, and a fourth light emitting unit, and the bridge electrode comprises a first bridge electrode, a second bridge electrode, and a third bridge electrode,
wherein the first light emitting unit and the second light emitting unit are connected through the first bridge electrode, the second light emitting unit and the third light emitting unit are connected through the second bridge electrode, and the third light emitting unit and the fourth light emitting unit are connected through the third bridge electrode.

10. The light emitting device according to claim 9, wherein the first light emitting unit, the second light emitting unit, the third light emitting unit, and the fourth light emitting unit are respectively located within four regions partitioned by two midlines of the base substrate, the first light emitting unit and the second light emitting unit are arranged in the second direction, the third light emitting unit and the fourth light emitting unit are arranged in the second direction, the first light emitting unit and the fourth light emitting unit are arranged in the first direction, and the second light emitting unit and the third light emitting unit are arranged in the first direction.

11. The light emitting device according to claim 10, wherein at least a portion of the first bridge electrode and at least a portion of the third bridge electrode are located between the first electrode and the second electrode, the second bridge electrode extends in the first direction, and is located on a side where short edges of the first electrode and the second electrode are located.

12. The light emitting device according to claim 11, wherein each of the first bridge electrode and the third bridge electrode extends in the second direction, and an orthographic projection of each of the first bridge electrode and the third bridge electrode on the base substrate does not overlap with orthographic projections of the first electrode and the second electrode on the base substrate, or
wherein each of the first bridge electrode and the third bridge electrode comprises a first portion extending in the first direction and a second portion extending in the second direction, orthographic projections of the first portion of the first bridge electrode and the first portion of the third bridge electrode on the base substrate respectively overlap with the orthographic projections of the first electrode and the second electrode on the base substrate, an orthographic projection of the second portion of the first bridge electrode on the base substrate does not overlap with the orthographic projection of the first electrode on the base substrate, and an orthographic projection of the second portion of the third bridge electrode does not overlap with the orthographic projection of the second electrode on the base substrate.

13. (canceled)

14. The light emitting device according to claim 9, wherein the bridge electrode further comprises a fourth bridge electrode and a fifth bridge electrode, the first light emitting unit and the second light emitting unit are also connected through the fourth bridge electrode, the third light emitting unit and the fourth light emitting unit are also connected through the fifth bridge electrode,
the fourth bridge electrode and the first bridge electrode are located on both sides of the first electrode, and the fifth bridge electrode and the second bridge electrode are located on both sides of the second electrode.

15. The light emitting device according to claim 9, wherein the first bridge electrode is Z-shaped, the second bridge electrode is L-shaped, and the third bridge electrode is L-shaped.

16. The light emitting device according to claim 9, wherein the first light emitting unit, the second light emitting unit, the third light emitting unit, and the fourth light emitting unit are respectively located in four regions partitioned by the two midlines of the base substrate, the first light emitting unit and the second light emitting unit are arranged in the second direction, the third light emitting unit and the fourth light emitting unit are arranged in the second direction, the first light emitting unit and the third light emitting unit are arranged in the first direction, and the second light emitting unit and the fourth light emitting unit are arranged in the first direction, the second bridge electrode comprises an inclined portion, and the inclined portion is inclined relative to the first direction and inclined relative to the second direction, and/or
wherein the third bridge electrode has a middle portion extending in the first direction and portions located on both sides of the middle portion and both extending in the second direction, wherein the second bridge electrode has an opening, and the opening of the second bridge electrode faces the first light emitting unit.

17. (canceled)

18. The light emitting device according to claim 15, wherein the bridge electrode further comprises a first connection electrode and a second connection electrode, an orthographic projection of the first connection electrode on the base substrate is located within an orthographic projection of the first light emitting unit on the base substrate, and an orthographic projection of the second connection electrode on the base substrate is located within an orthographic projection of the fourth light emitting unit on the base substrate, and/or
wherein the second bridge electrode has an opening, and the opening of the second bridge electrode faces the first light emitting unit.

19. (canceled)

20. The light emitting device according to claim 9, wherein the first light emitting unit, the second light emitting unit, the third light emitting unit, and the fourth light emitting unit are respectively located in four regions partitioned by two diagonals of a rectangle, the first light emitting unit and the fourth light emitting unit are arranged in the first direction, the second light emitting unit and the third light emitting unit are arranged in the second direction, and the second bridge electrode passes through an intersection of the two diagonals, and/or
wherein at least one selected from the group consisting of the first bridge electrode, the second bridge electrode, and the third bridge electrode has a bent portion.

21. (canceled)

22. The light emitting device according to claim 9, wherein the first light emitting unit, the second light emitting unit, the third light emitting unit, and the fourth light emitting unit are arranged in the second direction, the first bridge electrode and the second bridge electrode are respectively arranged on both sides of the second light emitting unit in the first direction, and the second bridge electrode and the third bridge electrode are respectively arranged on both sides of the third light emitting unit in the first direction, and/or
wherein at least one selected from the group consisting of the first bridge electrode, the second bridge electrode, and the third bridge electrode is Z-shaped.

23. (canceled)

24. The light emitting device according to claim 1, wherein a thickness of each of the first electrode and the second electrode is greater than or equal to 8 μm, and/or
wherein the thickness of each of the first electrode and the second electrode is less than or equal to 15 μm.

25. (canceled)

26. The light emitting device according to claim 1, wherein each of the first electrode and the second electrode comprises a first electrode portion and a second electrode portion that are stacked, and/or
wherein a material of the second electrode portion comprises solder, and the first electrode portion and the second electrode portion are made of different materials.

27. (canceled)

28. The light emitting device according to claim 9, further comprising a damage preventing structure, wherein the damage preventing structure is located within a region surrounded by the first light emitting unit, the second light emitting unit, the third light emitting unit, and the fourth light emitting unit, and no conductive structure is provided within a region where the damage preventing structure is located.

29. The light emitting device according to claim 1, further comprising a first passivation layer, a second passivation layer, and a third passivation layer, wherein the bridge electrode is located on the first passivation layer, the second passivation layer is located on the bridge electrode, the third passivation layer is located on the second passivation layer, and the third passivation layer also serves as a distributed Bragg reflector, or
the light emitting device further comprises a distributed Bragg reflector film layer, wherein the distributed Bragg reflector film layer is located on a side of the base substrate that is not provided with the plurality of light emitting units.

30-32. (canceled)

33. A display apparatus, comprising a backlight module, the backlight module comprising a light emitting substrate, the light emitting substrate comprising the light emitting device according to claim 1.
